(19) United States
(12) Patent Application Publication
(10) Pub. No.: US 2025/0169138 A1
(43) Pub. Date: May 22, 2025

(54) EXTENDED BACKSIDE CONTACT FOR STACKED FIELD-EFFECT TRANSISTOR

(71) Applicant: International Business Machines Corporation, Armonk, NY (US)

(72) Inventors: Ruilong Xie, Niskayuna, NY (US); Chen Zhang, Santa Clara, CA (US); Kisik Choi, Watervliet, NY (US); Tenko Yamashita, Schenectady, NY (US)

(21) Appl. No.: 18/517,129

(22) Filed: Nov. 22, 2023

(51) Int. Cl. H01L 29/66; H01L 21/8234; H01L 27/088; H01L 29/06; H01L 29/08; H01L 29/417; H01L 29/423; H01L 29/775; H01L 29/786

(52) U.S. Cl. CPC H10D 64/017; H10D 30/014; H10D 30/43; H10D 30/6735; H10D 30/6757; H10D 62/121; H10D 62/151; H10D 64/258; H10D 84/0149; H10D 84/038; H10D 84/83

(57) ABSTRACT

A semiconductor device comprises a first transistor comprising a first source/drain region disposed on a side of the first transistor, and a second transistor comprising a second source/drain region disposed on a side of the second transistor. A first source/drain contact is disposed under the first source/drain region, wherein sidewalls of the first source/drain contact are aligned with sidewalls of the first source/drain region. A second source/drain contact is disposed under the second source/drain region, wherein a dimension of the second source/drain contact is larger than a dimension of the second source/drain region such that at least one sidewall of the second source/drain contact is out of alignment with at least one sidewall of the second source/drain region. The second transistor comprises a plurality of channel layers contacting a dielectric layer of a gate cut portion.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower costs. Present technology is at or approaching atomic level scaling of certain micro-devices such as logic gates, field-effect transistors (FETs), and capacitors.

### SUMMARY

Embodiments of the invention provide structures for and techniques for forming an extended backside contact for a stacked FET.

In one embodiment, a semiconductor device a comprises a first transistor comprising a first source/drain region disposed on a side of the first transistor, and a second transistor comprising a second source/drain region disposed on a side of the second transistor. A first source/drain contact is disposed under the first source/drain region, wherein sidewalls of the first source/drain contact are aligned with sidewalls of the first source/drain region. A second source/drain contact is disposed under the second source/drain region, wherein a dimension of the second source/drain contact is larger than a dimension of the second source/drain region such that at least one sidewall of the second source/drain contact is out of alignment with at least one sidewall of the second source/drain region. The second transistor comprises a plurality of channel layers contacting a dielectric layer of a gate cut portion.

As may be combined with the preceding paragraph, a third transistor may be stacked on the first transistor and may comprise a third source/drain region disposed on a side of the third transistor, wherein the third source/drain region is stacked on the first source/drain region. A fourth transistor may be stacked on the second transistor and may comprise a fourth source/drain region disposed on a side of the fourth transistor, wherein the fourth source/drain region is stacked on the second source/drain region.

As may be combined with the preceding paragraphs, a via may be disposed along a side of the fourth source/drain region and the second source/drain region, wherein the at least one sidewall of the second source/drain contact contacts a sidewall of the via. The dielectric layer of the gate cut portion may be disposed between the fourth source/drain region and the via, and between the second source/drain region and the via. The fourth transistor may comprise a plurality of channel layers contacting the dielectric layer of the gate cut portion. The dielectric layer of the gate cut portion may be disposed between the via and the plurality of channel layers of the second transistor and between the via and the plurality of channel layers of the fourth transistor.

As may be combined with the preceding paragraphs, the via may be connected to a voltage source disposed on a first side of the semiconductor device, and the first and the second source/drain contacts may be disposed on a second side of the semiconductor device opposite the first side. The first source/drain contact may be connected to a voltage source disposed on the second side of the semiconductor device. The first and the second source/drain contacts may be disposed in a dielectric layer, and the first source/drain contact may be disposed at a greater depth in the dielectric layer than the second source/drain contact. The first transistor may comprise a gate-all-around transistor, and the second transistor may comprise a forksheet transistor.

Advantageously, a backside contact for a stacked FET has an enlarged size (e.g., larger horizontal dimension in the cross-sectional views) compared to a corresponding source/drain region on which the backside contact is formed. The backside contact is a shallow backside contact that is connected to frontside signal wires through a deep via. A liner dielectric layer isolates the deep via from channels of the stacked FET. Additionally, the backside contact connects to a sidewall of the deep via.

In another embodiment, a semiconductor device comprises a first transistor comprising a first source/drain region disposed on a side of the first transistor, and a second transistor stacked on the first transistor. The second transistor comprises a second source/drain region disposed on a side of the second transistor, wherein the second source/drain region is stacked on the first source/drain region. A source/drain contact is disposed under the first source/drain region, wherein a dimension of the source/drain contact is larger than a dimension of the first source/drain region such that at least one sidewall of the source/drain contact is out of alignment with at least one sidewall of the first source/drain region. The first transistor comprises a plurality of channel layers contacting a dielectric layer of a gate cut portion.

As may be combined with the preceding paragraphs, a via may be disposed along a side of the second source/drain region and the first source/drain region, wherein the at least one sidewall of the source/drain contact contacts a sidewall of the via. The dielectric layer of the gate cut portion may be disposed between the second source/drain region and the via, and between the first source/drain region and the via. The second transistor may comprise a plurality of channel layers contacting the dielectric layer of the gate cut portion, wherein the dielectric layer of the gate cut portion is disposed between the via and the plurality of channel layers of the second transistor.

As may be combined with the preceding paragraphs, the via may be connected to a voltage source disposed on a first side of the semiconductor device, and the source/drain contact may be disposed on a second side of the semiconductor device opposite the first side. The plurality of channel layers may contact the dielectric layer of the gate cut portion where the at least one sidewall of the source/drain contact is out of alignment with the at least one sidewall of the first source/drain region.

In another embodiment, a semiconductor device comprises a stacked structure comprising a plurality of gate structures alternately stacked with a plurality of channel layers, at least one source/drain region disposed on a side of the stacked structure, and a source/drain contact disposed under the at least one source/drain region. A dimension of the source/drain contact is larger than a dimension of the at least one source/drain region such that at least one sidewall of the source/drain contact is out of alignment with at least one sidewall of the at least one source/drain region. The plurality of channel layers contact a dielectric layer of a gate cut portion.

As may be combined with the preceding paragraphs, a via may be disposed along a side of the at least one source/drain region, wherein the at least one sidewall of the source/drain contact contacts a sidewall of the via. The dielectric layer of the gate cut portion may be disposed between the at least one source/drain region and the via. The dielectric layer of the gate cut portion may be disposed between the via and the plurality of gate structures and the plurality of channel layers.

These and other features and advantages of embodiments described herein will become more apparent from the accompanying drawings and the following detailed description.

### BRIEF DESCRIPTION OF THE DRAWINGS

FIG. 1A depicts a top view of a semiconductor structure with lines X, Y1 and Y2 on which the cross-sectional views of FIGS. 1B-4C are based, according to an embodiment of the invention.

FIG. 1B depicts a first cross-sectional view corresponding to the line X in FIG. 1A illustrating semiconductor nanosheet layers after dummy gate formation, according to an embodiment of the invention.

FIG. 1C depicts a second cross-sectional view corresponding to the line Y1 in FIG. 1A illustrating semiconductor nanosheet layers after dummy gate formation, according to an embodiment of the invention.

FIG. 1D depicts a third cross-sectional view corresponding to the line Y2 in FIG. 1A illustrating semiconductor nanosheet layers after dummy gate formation, according to an embodiment of the invention.

FIG. 2A depicts a first cross-sectional view corresponding to the line X in FIG. 1A following gate spacer formation, bottom dielectric insulator layer (BDI) formation, middle dielectric insulator layer (MDI) formation, lateral recessing of sacrificial semiconductor layers and inner spacer formation, according to an embodiment of the invention.

FIG. 2B depicts a second cross-sectional view corresponding to the line Y1 in FIG. 1A following gate spacer formation, BDI formation, MDI formation, lateral recessing of sacrificial semiconductor layers and inner spacer formation, according to an embodiment of the invention.

FIG. 2C depicts a third cross-sectional view corresponding to the line Y2 in FIG. 1A following gate spacer formation, BDI formation, MDI formation, lateral recessing of sacrificial semiconductor layers and inner spacer formation, according to an embodiment of the invention.

FIG. 3A depicts a first cross-sectional view corresponding to the line X in FIG. 1A following patterning for sacrificial placeholder layers, according to an embodiment of the invention.

FIG. 3B depicts a second cross-sectional view corresponding to the line Y1 in FIG. 1A following patterning for sacrificial placeholder layers, according to an embodiment of the invention.

FIG. 3C depicts a third cross-sectional view corresponding to the line Y2 in FIG. 1A following patterning for sacrificial placeholder layers, according to an embodiment of the invention.

FIG. 4A depicts a first cross-sectional view corresponding to the line X in FIG. 1A following sacrificial placeholder layer formation, source/drain region formation, inter-layer dielectric (ILD) layer formation, and replacement metal gate (RMG) formation, according to an embodiment of the invention.

FIG. 4B depicts a second cross-sectional view corresponding to the line Y1 in FIG. 1A following sacrificial placeholder layer formation, source/drain region formation, ILD layer formation, and RMG formation, according to an embodiment of the invention.

FIG. 4C depicts a third cross-sectional view corresponding to the line Y2 in FIG. 1A following sacrificial placeholder layer formation, source/drain region formation, ILD layer formation, and RMG formation, according to an embodiment of the invention.

FIG. 5A depicts a top view of a semiconductor structure with lines X, Y1 and Y2 on which the cross-sectional views of FIGS. 5B-5D are based, according to an embodiment of the invention.

FIG. 5B depicts a first cross-sectional view corresponding to the line X in FIG. 5A following additional ILD layer formation and gate cut patterning, according to an embodiment of the invention.

FIG. 5C depicts a second cross-sectional view corresponding to the line Y1 in FIG. 5A following additional ILD layer formation and gate cut patterning, according to an embodiment of the invention.

FIG. 5D depicts a third cross-sectional view corresponding to the line Y2 in FIG. 5A following additional ILD layer formation and gate cut patterning, according to an embodiment of the invention.

FIG. 6A depicts a top view of a semiconductor structure with lines X, Y1 and Y2 on which the cross-sectional views of FIGS. 6B-6D are based, according to an embodiment of the invention.

FIG. 6B depicts a first cross-sectional view corresponding to the line X in FIG. 6A following organic planarization layer (OPL) removal and bi-layer dielectric fill for gate cut portions, according to an embodiment of the invention.

FIG. 6C depicts a second cross-sectional view corresponding to the line Y1 in FIG. 6A following OPL removal and bi-layer dielectric fill for gate cut portions, according to an embodiment of the invention.

FIG. 6D depicts a third cross-sectional view corresponding to the line Y2 in FIG. 6A following OPL removal and bi-layer dielectric fill for gate cut portions, according to an embodiment of the invention.

FIG. 7A depicts a top view of a semiconductor structure with lines X, Y1 and Y2 on which the cross-sectional views of FIGS. 7B-7D are based, according to an embodiment of the invention.

FIG. 7B depicts a first cross-sectional view corresponding to the line X in FIG. 7A following deep via patterning, according to an embodiment of the invention.

FIG. 7C depicts a second cross-sectional view corresponding to the line Y1 in FIG. 7A following deep via patterning, according to an embodiment of the invention.

FIG. 7D depicts a third cross-sectional view corresponding to the line Y2 in FIG. 7A following deep via patterning, according to an embodiment of the invention.

FIG. 8A depicts a top view of a semiconductor structure with lines X, Y1 and Y2 on which the cross-sectional views of FIGS. 8B-15C are based, according to an embodiment of the invention.

FIG. 8B depicts a first cross-sectional view corresponding to the line X in FIG. 8A following middle-of-line (MOL) contact formation, back-end-of-line (BEOL) interconnect formation and carrier wafer bonding, according to an embodiment of the invention.

FIG. 8C depicts a second cross-sectional view corresponding to the line Y1 in FIG. 8A following MOL contact formation, BEOL interconnect formation and carrier wafer bonding, according to an embodiment of the invention.

FIG. 8D depicts a third cross-sectional view corresponding to the line Y2 in FIG. 8A following MOL contact formation, BEOL interconnect formation and carrier wafer bonding, according to an embodiment of the invention.

FIG. 9A depicts a first cross-sectional view corresponding to the line X in FIG. 8A following wafer flipping and semiconductor substrate removal, according to an embodiment of the invention.

FIG. 9B depicts a second cross-sectional view corresponding to the line Y1 in FIG. 8A following wafer flipping and semiconductor substrate removal, according to an embodiment of the invention.

FIG. 9C depicts a third cross-sectional view corresponding to the line Y2 in FIG. 8A following wafer flipping and semiconductor substrate removal, according to an embodiment of the invention.

FIG. 10A depicts a first cross-sectional view corresponding to the line X in FIG. 8A following etch stop layer and remaining semiconductor substrate removal, according to an embodiment of the invention.

FIG. 10B depicts a second cross-sectional view corresponding to the line Y1 in FIG. 8A following etch stop layer and remaining semiconductor substrate removal, according to an embodiment of the invention.

FIG. 10C depicts a third cross-sectional view corresponding to the line Y2 in FIG. 8A following etch stop layer and remaining semiconductor substrate removal, according to an embodiment of the invention.

FIG. 11A depicts a first cross-sectional view corresponding to the line X in FIG. 8A following backside ILD layer formation and planarization, according to an embodiment of the invention.

FIG. 11B depicts a second cross-sectional view corresponding to the line Y1 in FIG. 8A following backside ILD layer formation and planarization, according to an embodiment of the invention.

FIG. 11C depicts a third cross-sectional view corresponding to the line Y2 in FIG. 8A following backside ILD layer formation and planarization, according to an embodiment of the invention.

FIG. 12A depicts a first cross-sectional view corresponding to the line X in FIG. 8A following sacrificial placeholder layer removal, according to an embodiment of the invention.

FIG. 12B depicts a second cross-sectional view corresponding to the line Y1 in FIG. 8A following sacrificial placeholder layer removal, according to an embodiment of the invention.

FIG. 12C depicts a third cross-sectional view corresponding to the line Y2 in FIG. 8A following sacrificial placeholder layer removal, according to an embodiment of the invention.

FIG. 13A depicts a first cross-sectional view corresponding to the line X in FIG. 8A following backside contact formation and planarization, according to an embodiment of the invention.

FIG. 13B depicts a second cross-sectional view corresponding to the line Y1 in FIG. 8A following backside contact formation and planarization, according to an embodiment of the invention.

FIG. 13C depicts a third cross-sectional view corresponding to the line Y2 in FIG. 8A following backside contact formation and planarization, according to an embodiment of the invention.

FIG. 14A depicts a first cross-sectional view corresponding to the line X in FIG. 8A following backside contact recessing to define one or more shallow backside contacts, according to an embodiment of the invention.

FIG. 14B depicts a second cross-sectional view corresponding to the line Y1 in FIG. 8A following backside contact recessing to define one or more shallow backside contacts, according to an embodiment of the invention.

FIG. 14C depicts a third cross-sectional view corresponding to the line Y2 in FIG. 8A following backside contact recessing to define one or more shallow backside contacts, according to an embodiment of the invention.

FIG. 15A depicts a first cross-sectional view corresponding to the line X in FIG. 8A following backside power delivery network (BSPDN) formation, according to an embodiment of the invention.

FIG. 15B depicts a second cross-sectional view corresponding to the line Y1 in FIG. 8A following BSPDN formation, according to an embodiment of the invention.

FIG. 15C depicts a third cross-sectional view corresponding to the line Y2 in FIG. 8A following BSPDN formation, according to an embodiment of the invention.

### DETAILED DESCRIPTION

Illustrative embodiments of the invention may be described herein in the context of illustrative methods for forming an extended backside contact for a stacked FET, along with illustrative apparatus, systems and devices formed using such methods. However, it is to be understood that embodiments of the invention are not limited to the illustrative methods, apparatus, systems and devices but instead are more broadly applicable to other suitable methods, apparatus, systems and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

A field-effect transistor (FET) is a transistor having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the size of FETs. One technique is through the use of fin-shaped channels in FinFET devices. Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures the gate can more effectively control the channel, as the gate extends over more than one side or surface of the channel. In some FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheets may be two-dimensional nanostructures, such as sheets having a thickness range on the order of 1 to 100 nanometers (nm). Nanosheets and nanowires are viable options for scaling to 7 nm and beyond. A general process flow for formation of a nanosheet stack involves selectively removing sacrificial layers, which may be formed of silicon germanium (SiGe) between sheets of channel material, which may be formed of silicon (Si).

For continued scaling (e.g., to 2.5 nm and beyond), next-generation stacked FET devices may be used. Next-generation stacked FET devices provide a complex gate-all-around (GAA) structure. Conventional GAA FETs, such as nanosheet FETs, may stack multiple p-type nanowires or nanosheets on top of each other in one device, and may stack multiple n-type nanowires or nanosheets on top of each other in another device. Next-generation stacked FET structures provide improved track height scaling, leading to structural gains (e.g., such as 30-40% structural gains for different types of devices, such as logic devices, static random-access memory (SRAM) devices, etc.). In next-generation stacked FET structures, n-type and p-type nanowires or nanosheets are stacked on each other, eliminating n-to-p separation bottlenecks and reducing the device area footprint. There is, however, a continued desire for further scaling and reducing the size of FETs.

As discussed above, various techniques may be used to reduce the size of FETs, including through the use of fin-shaped channels in FinFET devices, through the use of stacked nanosheet channels formed over a semiconductor substrate, and next-generation stacked FET devices.

Although embodiments of the present invention are discussed in connection with nanosheet stacks, the embodiments of the present invention are not necessarily limited thereto, and may similarly apply to nanowire stacks.

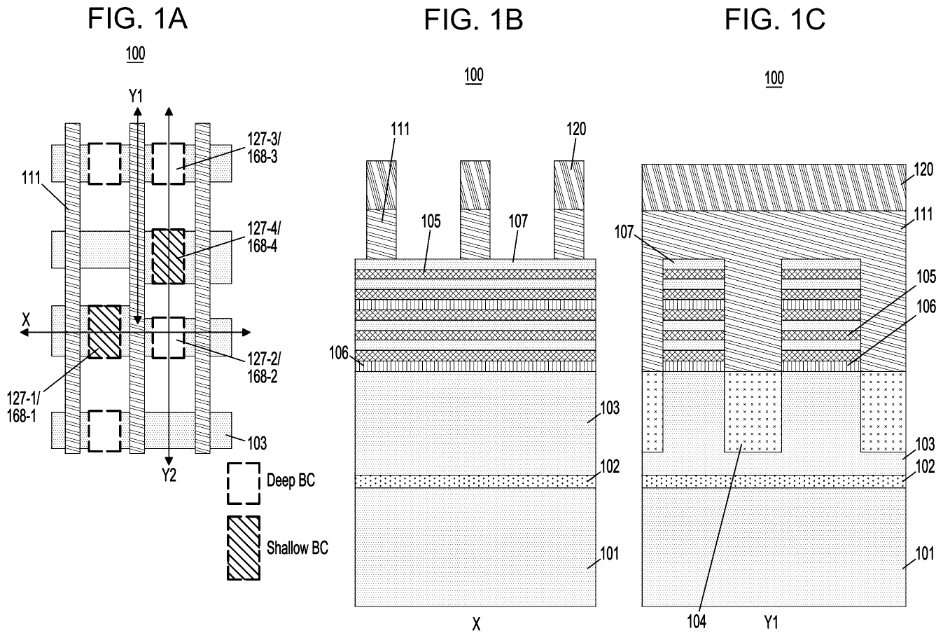

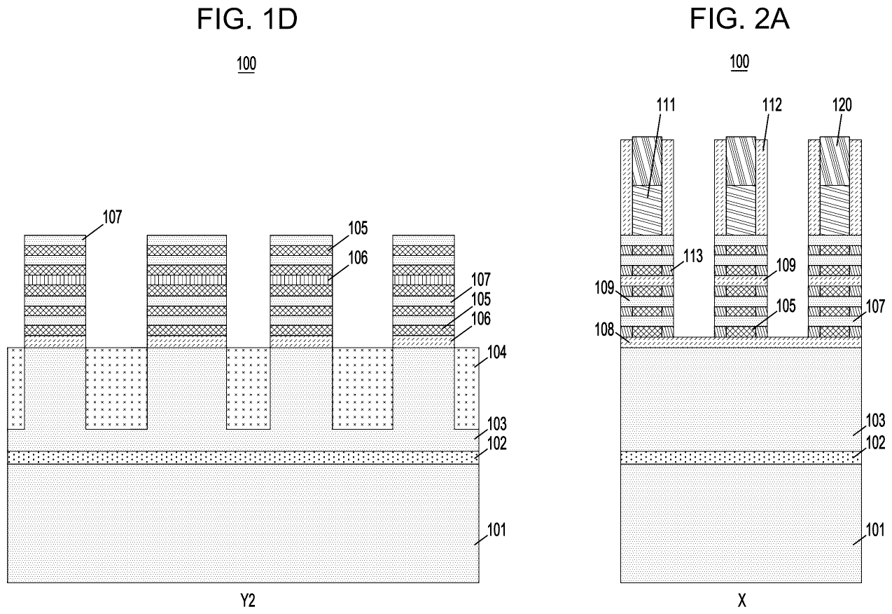

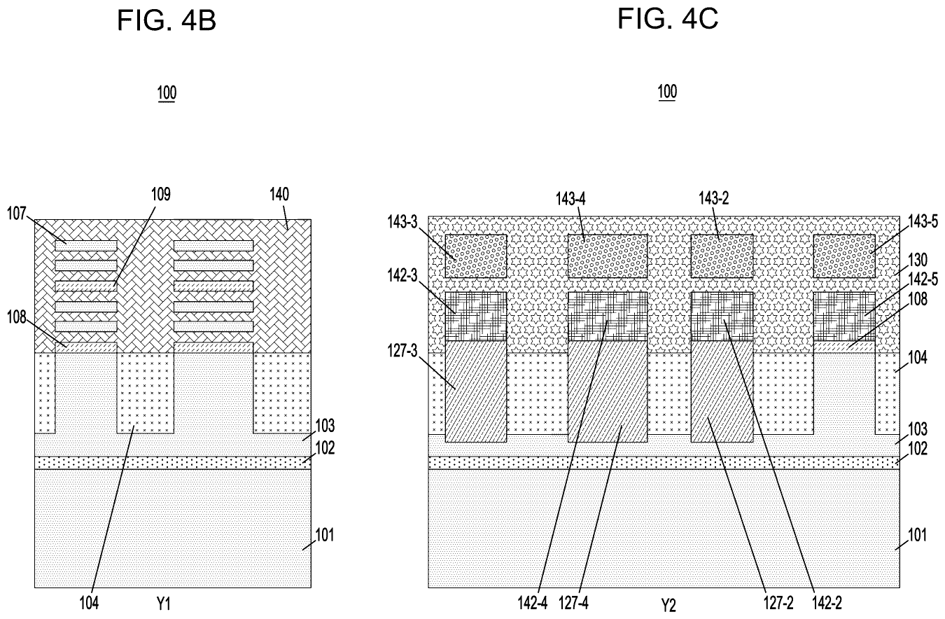

FIG. 1A depicts a top view of a semiconductor structure 100 with lines X, Y1 and Y2 on which the cross-sectional views of FIGS. 1B-4C are based. FIG. 1A illustrates dummy gate portions 111 and portions of a second semiconductor substrate 103 corresponding to where sacrificial placeholder layers 127-1, 127-2, 127-3 and 127-4 (collectively “sacrificial placeholder layers 127”) and backside source/drain contacts 168-1, 168-2, 168-3 and 168-4 (collectively “backside source/drain contacts 168”) will be formed. The backside source/drain contacts 168 may be deep or shallow backside contacts (“Deep BC” or “Shallow BC”). The sacrificial placeholder layers 127 and backside source/drain contacts 168 are described in more detail herein in connection with, for example, FIGS. 4A-4C and 13A-15C. As shown in FIG. 1A, when a shallow backside contact (e.g., backside source/drain contacts 168-4 and 168-1) is needed, a size of the active region (Rx) is locally increased such that it is larger than a target size. The target size corresponds to a size of the active regions (Rx) in locations where deep backside contacts (e.g., backside source/drain contacts 168-2 and 168-3). This will facilitate backside contact extension fabrication, which is explained in more detail herein below.

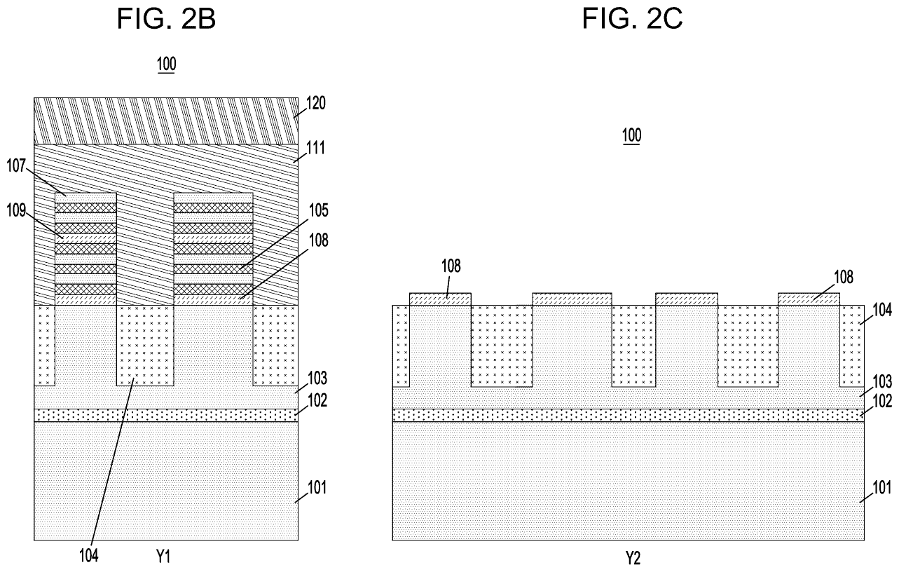

Referring to FIG. 1A and to the cross-sectional views in FIGS. 1B, 1C and 1D, which respectively correspond to the lines X, Y1 and Y2 in FIG. 1A, a semiconductor structure 100 includes a stacked structure of first sacrificial layers 105, second sacrificial layers 106 and channel layers 107. In an illustrative embodiment, the first and second sacrificial layers 105 and 106 comprise silicon germanium (SiGe) and the channel layers 107 comprise silicon. In illustrative embodiments, the first sacrificial layers 105 comprise a germanium concentration of about 30% (e.g., SiGe30) and the second sacrificial layers 106 comprise a germanium concentration of about 60% (e.g., SiGe60), but the embodiments are not necessarily limited to SiGe30 and SiGe60 for the first and second sacrificial layers 105 and 106. The lowermost first sacrificial layer 105 for a first (lower) transistor of two stacked transistors is formed on a lowermost second sacrificial layer 106 and a lowermost first sacrificial layer 105 for a second (upper) transistor of two stacked transistors is formed on the uppermost second sacrificial layer 106. As explained in more detail herein, the second sacrificial layers 106 have a different concentration of germanium than the first sacrificial layers 105 so that the second sacrificial layers 106 can be selectively etched and removed with respect to first sacrificial layers 105 when forming bottom dielectric isolation (BDI) and middle dielectric isolation (MDI) layers 108 and 109 (see, e.g., FIGS. 2A-2C).

Referring to FIGS. 1B-1D, a first semiconductor substrate 101 and a second semiconductor substrate 103 comprise semiconductor material including, but not limited to, silicon, III-V, II-V compound semiconductor materials or other like semiconductor materials. In addition, multiple layers of the semiconductor materials can be used as the semiconductor material of the first and second semiconductor substrates 101 and 103. An etch stop layer 102 is formed on the first semiconductor substrate 101. In an illustrative embodiment, the etch stop layer 102 comprises SiGe (e.g., SiGe30) or silicon dioxide (SiO₂) and the first and second semiconductor substrates 101 and 103 comprise silicon.

According to one or more embodiments, the etch stop layer 102 is epitaxially grown on the first semiconductor substrate 101, the second semiconductor substrate 103 is epitaxially grown on the etch stop layer 102 and the lowermost second sacrificial layer 106 is epitaxially grown on the second semiconductor substrate 103. The first sacrificial layers 105 and channel layers 107 corresponding to lower transistors of stacked transistors are epitaxially grown in an alternating and stacked configuration on the lowermost second sacrificial layer 106. Then, the uppermost second sacrificial layer 106 is epitaxially grown on an uppermost first sacrificial layer 105 of the lower transistors. The first sacrificial layers 105 and channel layers 107 corresponding to upper transistors of stacked transistors are epitaxially grown in an alternating and stacked configuration on the uppermost second sacrificial layer 106. In either case, a first one of the first sacrificial layers 105 is followed by a first channel layer 107 on the first one of the first sacrificial layers 105, which is followed by a second one of the first sacrificial layers 105 on the first channel layer 107, and so on. As can be understood, the first sacrificial layers 105 and channel layers 107 are epitaxially grown from their corresponding underlying semiconductor layers.

The embodiments are not necessarily limited to the shown number of first sacrificial layers 105 and channel layers 107, and there may be more or less layers in the same alternating configuration depending on design constraints. The first sacrificial layers 105, as described further herein, are eventually removed and replaced by gate structures.

Although SiGe is described as a sacrificial material for first sacrificial layers 105, other materials can be used as long as the first sacrificial layers 105 have the property of being able to be removed selectively compared to the material of the channel layers 107.

The terms “epitaxial growth and/or deposition” and “epitaxially formed and/or grown,” mean the growth of a semiconductor material (crystalline material) on a deposition surface of another semiconductor material (crystalline material), in which the semiconductor material being grown (crystalline over layer) has substantially the same crystalline characteristics as the semiconductor material of the deposition surface (seed material). In an epitaxial deposition process, the chemical reactants provided by the source gases are controlled, and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed.

The epitaxial deposition process may employ the deposition chamber of a chemical vapor deposition type apparatus, such as a metal-organic chemical vapor deposition (MOCVD), rapid thermal chemical vapor deposition (RTCVD), ultra-high vacuum chemical vapor deposition (UHVCVD), or a low-pressure chemical vapor deposition (LPCVD) apparatus. A number of different sources may be used for the epitaxial deposition of the in situ doped semiconductor material. In some embodiments, the gas source for the deposition of an epitaxially formed semiconductor material may include silicon (Si) deposited from silane, disilane, trisilane, tetrasilane, hexachlorodisilane, tetrachlorosilane, dichlorosilane, trichlorosilane, and combinations thereof. In other examples, when the semiconductor material includes germanium, a germanium gas source may be selected from the group consisting of germane, digermane, halogermane, dichlorogermane, trichlorogermane, tetrachlorogermane and combinations thereof. The temperature for epitaxial deposition typically ranges from 450° C. to 900° C. Although higher temperature typically results in faster deposition, the faster deposition may result in crystal defects and film cracking.

In a non-limiting illustrative embodiment, a height of the first sacrificial layers 105 can be in the range of about 6 nm to about 15 nm depending on the application of the device. Also, in a non-limiting illustrative embodiment, a height of the channel layers 107 can be in the range of about 6 nm to about 15 nm depending on the desired process and application. In accordance with an embodiment of the present invention, each of the channel layers 107 has the same or substantially the same composition and size as each other, and each of the sacrificial layers 105 has the same or substantially the same composition and size as each other.

As used herein, “frontside or “first side” refers to a side on top of the second semiconductor substrate 103 and/or in front of, on top of or in an upward direction from the stacked nanosheet/gate and channel layers of the transistors in the orientation shown in the cross-sectional figures. As used herein, “backside” or “second side” refers to a side below the semiconductor substrate 103 and/or behind, under, below or in a downward direction from the stacked nanosheet/gate and channel layers of the transistors in the orientation shown in the cross-sectional figures (e.g., opposite the “frontside”).

Portions of the nanosheet stacks comprising the first and second sacrificial layers 105 and 106 and channel layers 107 are removed, and portions of the second semiconductor substrate 103 are recessed. Isolation regions 104 (e.g., shallow trench isolation (STI)) regions are formed between the remaining nanosheet stacks in the recessed portions of the second semiconductor substrate 103. Isolation regions 104 comprising dielectric material fill in the recessed portions of the second semiconductor substrate 103. The dielectric material may comprise, for example, SiO₂, silicon nitride (SiN), silicon oxynitride (SiON), silicon-carbon-nitride (SiCN), boron nitride (BN), silicon boron nitride (SiBN), silicoboron carbonitride (SiBCN), silicon oxycarbonitride (SiOCN) and combinations thereof, and is deposited using deposition techniques such as, for example, chemical vapor deposition (CVD), plasma enhanced CVD (PECVD), radio-frequency CVD (RFCVD), physical vapor deposition (PVD), atomic layer deposition (ALD), molecular beam deposition (MBD), pulsed laser deposition (PLD), and/or liquid source misted chemical deposition (LSMCD).

Dummy gate portions 111 are formed on the uppermost channel layers 107 and around the stacked nanosheet configurations of the first and second sacrificial layers 105 and 106 and channel layers 107. The dummy gate portions 111 include, but are not necessarily limited to, an amorphous silicon (a-Si) layer. The dummy gate portions 111 are deposited using deposition techniques such as, for example, CVD, PECVD, RFCVD, PVD, ALD, MBD, PLD, LSMCD, sputtering and/or plating, followed by a planarization process, such as, chemical mechanical planarization (CMP), and lithography and etching steps to remove excess dummy gate material, and pattern the deposited layer. Hardmask layers 120 are formed on the dummy gate portions 111. The hardmask layers 120 comprise, for example, a nitride such as SiN or other nitride material.

Referring to FIGS. 2A-2C, remaining portions of the second sacrificial layers 106 are removed using, for example, a plasma dry etch that contains HCl gas chemistry to selectively etch the portions of the second sacrificial layers 106 with respect to the portions of the second semiconductor substrate 103, the first sacrificial layers 105 and the channel layers 107. The selective etching removes the remaining portions of the second sacrificial layers 106 to form vacant areas where the BDI and MDI layers 108 and 109 will be formed.

Following the removal of the remaining portions of the second sacrificial layers 106, dielectric material is deposited in place of the remaining portions of the second sacrificial layers 106 using deposition techniques such as, for example, CVD, PECVD, RFCVD, PVD, ALD, MBD, PLD, and/or LSMCD, followed by an etch back to form the BDI and MDI layers 108 and 109. The BDI and MDI layers 108 and 109 may comprise, for example, silicon oxide (SiOₓ) (where x is for example, 2, 1.99 or 2.01), silicon oxycarbide (SiOC), SiN, SiON, SiCN, BN, SiBCN, SiOCN or some other dielectric.

Gate spacers 112 are formed on sides of the hardmask layers 120 and dummy gate portions 111 by one or more of the deposition techniques noted in connection with deposition of the dummy gate material. The spacer material can comprise for example, one or more dielectrics, including, but not necessarily limited to, SiN, SiON, SiOC, SiCN, BN, SiBN, SiBCN, SiOCN, SiOₓ, and combinations thereof. According to an embodiment, the hardmask layers 120 and gate spacers 112 can be the same material or different materials. The gate spacers 112 can be formed by any suitable technique such as deposition followed by directional etching. Deposition may include, but is not limited to, ALD or CVD. Directional etching may include but is not limited to, reactive ion etching (RIE).

Exposed portions of the stacked first sacrificial layers 105, channel layers 107 and MDI layers 109, which are not under the hardmask layers 120, gate spacers 112 and dummy gate portions 111, are removed using, for example, an etching process, such as RIE, where the hardmask layers 120, gate spacers 112 and dummy gate portions 111 are used as a mask. The portions of the stacked structures of the first sacrificial layers 105, channel layers 107 and MDI layers 109 under the hardmask layers 120, gate spacers 112 and under the dummy gate portions 111 remain after the etching process, and portions of the first sacrificial layers 105, channel layers 107 and MDI layers 109 in areas that correspond to where source/drain regions will be formed are removed. Initially, in the exposed areas, the etching is stopped at the BDI layer 108. Portions of the top surface of the BDI layer 108 on sides of the stacked structures of the first sacrificial layers 105 and channel layers 107 are exposed.

Due to, for example, germanium in the first sacrificial layers 105, lateral etching of the first sacrificial layers 105 can be performed selective to the channel layers 107, such that the side portions of the first sacrificial layers 105 can be removed to create vacant areas to be filled in by inner spacers 113. The material of the inner spacers 113 can comprise, but is not necessarily limited to, a nitride, such as, SiN, SiON, SiCN, BN, SiBN, SiBCN or SiOCN. Gate spacers 112 are positioned on the nanosheet stacks on opposite lateral sides of the dummy gate portions 111. In an illustrative embodiment, the gate spacers 112 are formed from the same or similar material to that of the inner spacers 113. Like the gate spacers 112, the inner spacers 113 can be formed by any suitable techniques such as deposition followed by isotropic etching.

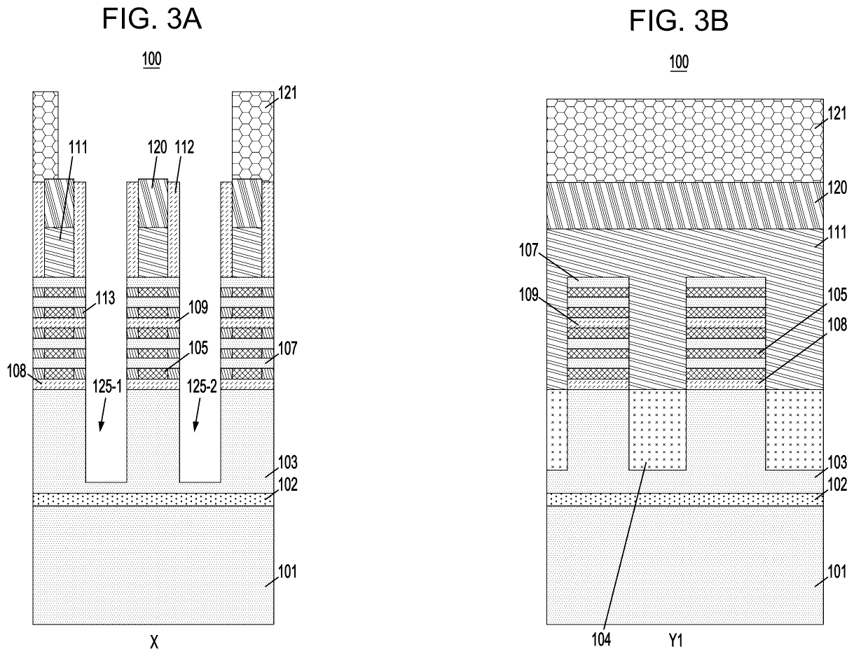

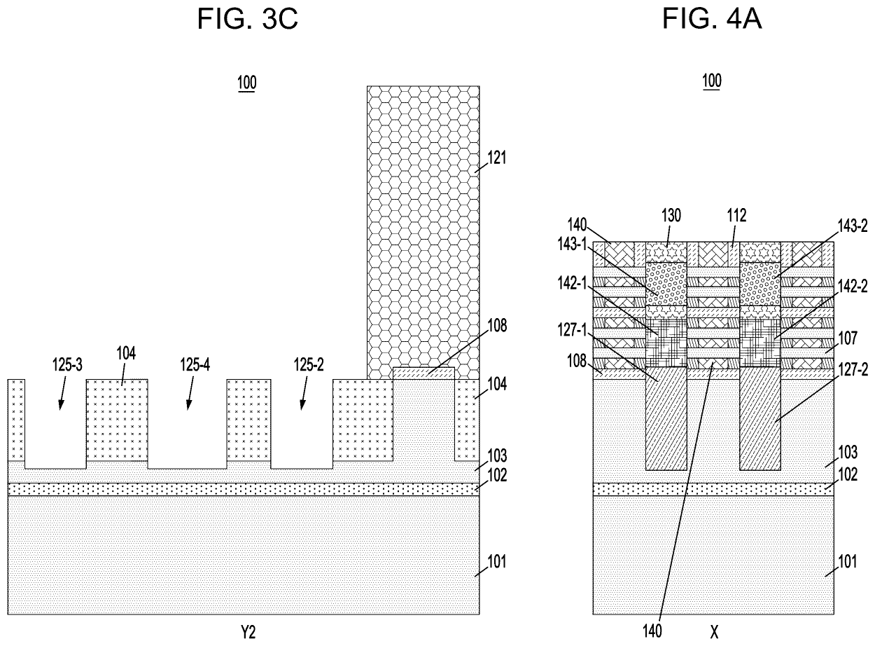

Referring to FIGS. 3A-3C, organic planarization layer (OPLs) 121 are formed on portions of the hardmask layers 120, portions of the isolation regions 104 and portions of the exposed BDI layer 108. The OPLs 121 comprise, but are not necessarily limited to, an organic polymer including C, H, and N. In an embodiment, the OPL material can be free of silicon (Si). According to an embodiment, the OPL material can be free of Si and fluorine (F). As defined herein, a material is free of an atomic element when the level of the atomic element in the material is at or below a trace level detectable with analytic methods available in the art. Non-limiting examples of the OPL material include JSR HM8006, JSR HM8014, AZ UM10M2, Shin Etsu ODL-102, or other similar commercially available materials from such vendors as JSR, TOK, Sumitomo, Rohm & Haas, etc. The OPLs 121 can be deposited, for example, by spin coating.

Exposed portions of the BDI layer 108 are removed in a first removal process. The exposed portions are between the stacked structures of first sacrificial layers 105, channel layers 107, protected portions of BDI layer 108 and MDI layer 109. Following removal of the exposed portions of the BDI layer 108 between the stacked structures, underlying portions of the second semiconductor substrate 103 are removed, such that portions of the second semiconductor substrate 103 are recessed to create openings (also referred to herein as “trenches”) 125-1, 125-2, 125-3 and 125-4 (collectively “trenches 125”) in the second semiconductor substrate 103. The second semiconductor substrate 103 can be etched using, for example, a dry etch process. As can be seen, the exposed portions of the second semiconductor substrate 103 are recessed below the bottom surfaces of the remaining portions of the BDI layer 108 and below top surfaces of the isolation regions 104 to a depth near the etch stop layer 102.

Referring to FIGS. 4A-4C, sacrificial placeholder layers 127 are formed in the trenches 125. In more detail, the OPLs 121 are removed, and the trenches 125 are filled with sacrificial placeholder layers 127 comprising, for example, SiGe, III-V semiconductor material or other semiconductor material. The OPLs 121 are stripped using, for example, oxygen plasma, nitrogen/hydrogen plasma or other carbon strip process. OPL stripping causes minimal or no damage to exposed layers. The sacrificial placeholder layers 127 are deposited in the trenches 125 using deposition techniques such as, for example, epitaxial growth, CVD, PECVD, RFCVD, PVD, ALD, MBD, PLD, and/or LSMCD. The top surfaces of the sacrificial placeholder layers 127 extend to a height above the top surfaces of the isolation regions 104 and the second semiconductor substrate 103 and are co-planar with top surfaces of the BDI layer 108. The locally larger active size for locations that need shallow backside contacts enables formation of placeholders (e.g., sacrificial placeholder 127-4) with a larger lateral size than placeholders corresponding to deep backside contacts (e.g., sacrificial placeholders 127-2 or 127-3). As discussed in more detail herein, the larger lateral size facilitates backside contact extension formation.

Bottom source/drain regions 142-1, 142-2, 142-3, 142-4 and 142-5 (collectively “bottom source/drain regions 142”) and top source/drain regions 143-1, 143-2, 143-3, 143-4 and 143-5 (collectively “top source/drain regions 143”) are epitaxially grown between the nanosheet stacks. The bottom source/drain regions 142 correspond to lower transistors and the top source/drain regions 143 correspond to upper transistors of stacked structures of respective lower and upper transistors. The bottom and top source/drain regions 142 and 143 comprise epitaxial layers grown from sides of channel layers 107 and/or from top surfaces of the sacrificial placeholder layers 127. As can be seen, the bottom source/drain regions 142 are formed on and contact corresponding ones of underlying sacrificial placeholder layers 127. The horizontal dimension (e.g., width) of the bottom and top source/drain regions 142 and 143 in FIGS. 4A and 4C corresponds to the horizontal dimension of the underlying sacrificial placeholder layers 127 and to the space between nanosheet stacks.

Side surfaces of respective ones of the channel layers 107 contact a side surface of at least one adjacent top or bottom source/drain region 143 or 142. The top surfaces of the top or bottom source/drain regions 143 or 142 are above the top surfaces of uppermost ones of the channel layers 107 for the lower and upper transistors of a transistor stack.

According to a non-limiting embodiment of the present invention, the conditions of the epitaxial growth process for the bottom and top source/drain regions 142 and 143 are, for example, RTCVD epitaxial growth using SiH₄, SiH₂Cl₂, GeH₄, CH₃SiH₃, B₂H₆, PF₃, and/or H₂ gases with temperature and pressure ranges of about 450° C. to about 800° C., and about 5 Torr-about 300 Torr. In the case of n-type FETS (nFETs), the bottom or top source/drain regions 142 and 143 can comprise silicon doped with n-type dopants including, for example, phosphorus (P), arsenic (As) and antimony (Sb). In the case of p-type FETS (pFETs), the bottom or top source/drain regions 142 and 143 can comprise silicon doped with n-type dopants including, for example, boron (B), boron fluoride (BF₂), gallium (Ga), indium (In), and thallium (Tl).

An inter-layer dielectric (ILD) layer 130 is deposited to fill in portions on and around the bottom and top source/drain regions 142 and 143. The ILD layer 130 is deposited using deposition techniques such as, for example, CVD, PECVD, RFCVD, PVD, ALD, MBD, PLD, and/or LSMCD, followed by a planarization process, such as, chemical mechanical planarization (CMP) to remove excess portions of the ILD layer 130 deposited on top of the hardmask layers 120 and gate spacers 112, and to remove the hardmask layers 120 and portions of the gate spacers 112 to expose the dummy gate portions 111. The ILD layer 130 may comprise, for example, SiOx, SiOC, SiOCN or some other dielectric.

Dummy gate portions 111 are selectively removed to create vacant areas where gate structures will be formed in place of the dummy gate portions 111. The selective removal can be performed using, for example, hot ammonia to remove a-Si. In addition, the first sacrificial layers 105 are selectively removed to create vacant areas where gate structures will be formed in place of the first sacrificial layers 105. The first sacrificial layers 105 are selectively removed with respect to the channel layers 107. The selective removal can be performed using, for example, a dry HCl etch.

Following removal of the dummy gate portions 111 and first sacrificial layers 105, the channel layers 107 are suspended, and gate structures 140, including, for example, gate and dielectric portions are formed in the vacant portions left by removal of the dummy gate portions 111, and the first sacrificial layers 105. In illustrative embodiments, each gate structure 140 includes a gate dielectric layer such as, for example, a high-K dielectric layer including, but not necessarily limited to, HfO₂ (hafnium oxide), ZrO₂ (zirconium dioxide), hafnium zirconium oxide, Al₂O₃(aluminum oxide), and Ta₂O₅ (tantalum oxide). Examples of high-k materials also include, but are not limited to, metal oxides such as hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. According to an embodiment, the gate structures 140 each include a metal gate portion including a work-function metal (WFM) layer, including but not necessarily limited to, for a pFET, titanium nitride (TiN), tantalum nitride (TaN) or ruthenium (Ru), and for an nFET, TiN, titanium aluminum nitride (TiAlN), titanium aluminum carbon nitride (TiAlCN), titanium aluminum carbide (TiAlC), tantalum aluminum carbide (TaAlC), tantalum aluminum carbon nitride (TaAlCN) or lanthanum (La) doped TiN, TaN, which can be deposited on the gate dielectric layer. The metal gate portions can also each further include a gate metal layer including, but not necessarily limited to, metals, such as, for example, tungsten, cobalt, zirconium, tantalum, titanium, aluminum, ruthenium, copper, metal carbides, metal nitrides, transition metal aluminides, tantalum carbide, titanium carbide, tantalum magnesium carbide, or combinations thereof deposited on the WFM layer and the gate dielectric layer. It should be appreciated that various other materials may be used for the metal gate portions as desired.

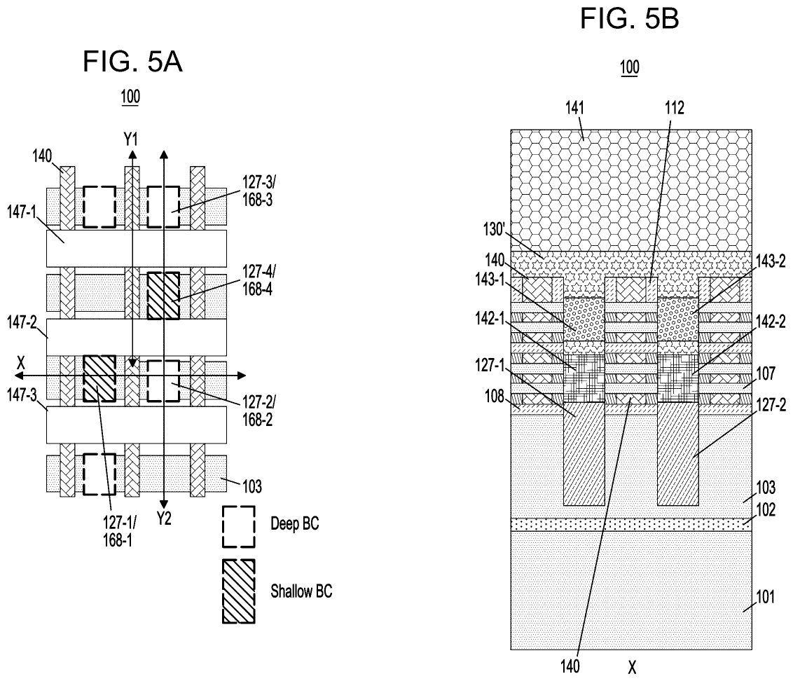

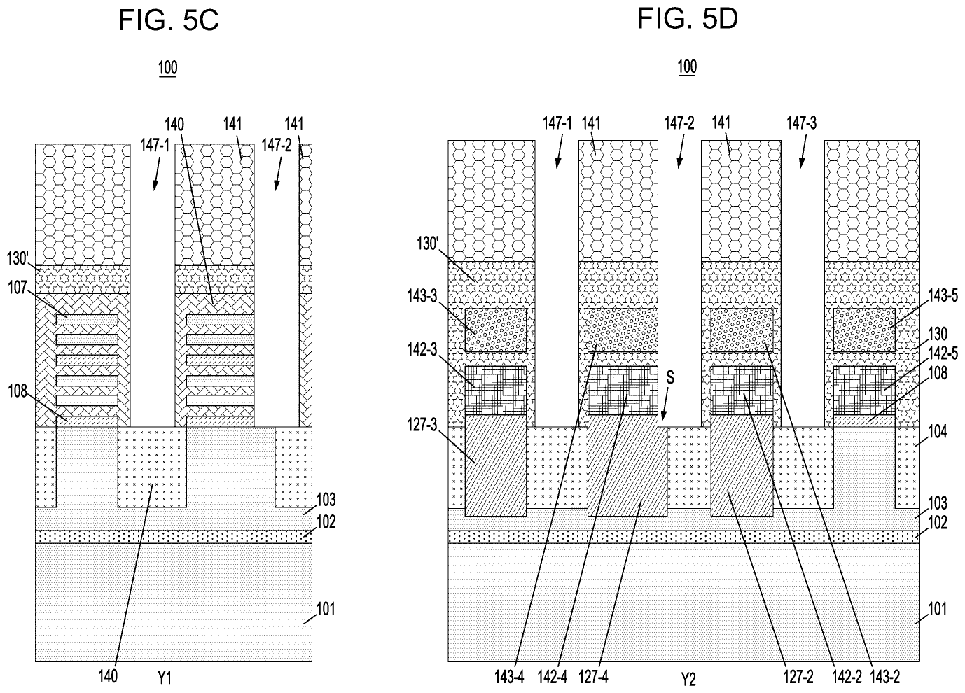

FIG. 5A depicts a top view of the semiconductor structure 100 with lines X, Y1 and Y2 on which the cross-sectional views of FIGS. 5B-5D are based, according to an embodiment of the invention. Referring to FIGS. 5A-5D, additional ILD material is deposited to form an additional ILD layer 130′ on top of the ILD layer 130. OPLs 141 are deposited on portions of the additional ILD layer 130′. Exposed parts of the additional ILD layer 130′ and underlying portions of the gate structures 140 and/or ILD layer 130 where the OPLs 141 are not formed are removed down to the isolation regions 104 to create openings 147-1, 147-2 and 147-3 (collectively “openings 147”) where gate cut portions will be formed. As can be seen, the openings 147 are formed between the nanosheet stacks comprising the channel layers 107 and gate structures 140, and between the bottom and top source/drain regions 142 and 143. Referring to FIGS. 5C and 5D, in forming the opening 147-2, parts of bottom and top source/drain regions 142-4 and 143-4, and sacrificial placeholder layer 127-4 are removed. The opening 147-2 exposes respective sidewalls of the bottom and top source/drain regions 142-4 and 143-4 and respective sidewalls of channel layers 107, BDI layer 108 and MDI layer 109. A stepped portion S of sacrificial placeholder layer 127-4 is formed. The removal of the parts of the additional ILD layer 130′, the ILD layer 130 and the gate structure 140 to form the openings 147 is performed using, for example, RIE. By forming openings 147-1, 147-2 and 147-3 for gate cut patterning, the active region size for locations that require shallow backside contact is reduced to the target size. Although the sizes of the channel layers 107 and bottom and top source/drain regions 142-4, 143-4 corresponding to where the shallow backside contact (e.g., backside source/drain contact 168-4) will be formed are reduced by opening 147-2, the size of the sacrificial placeholder 127-4 remains larger than the target size to facilitate backside contact extension formation.

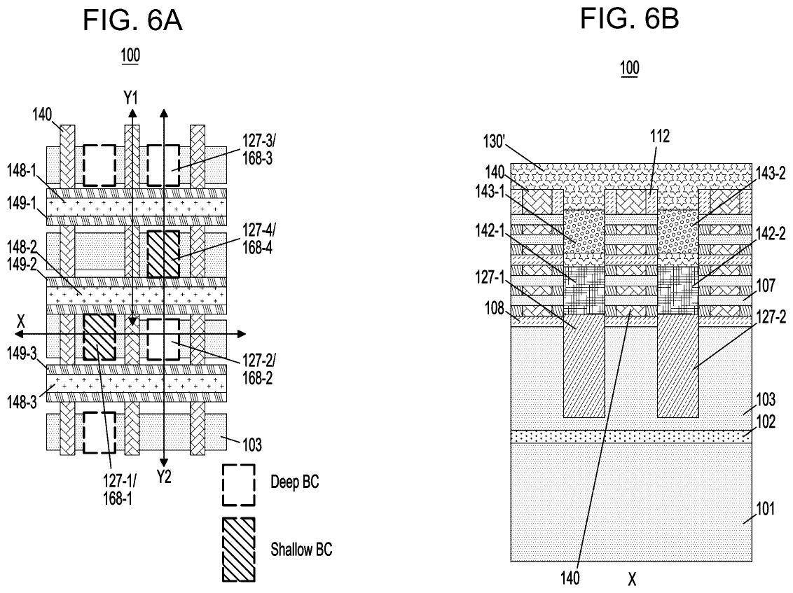

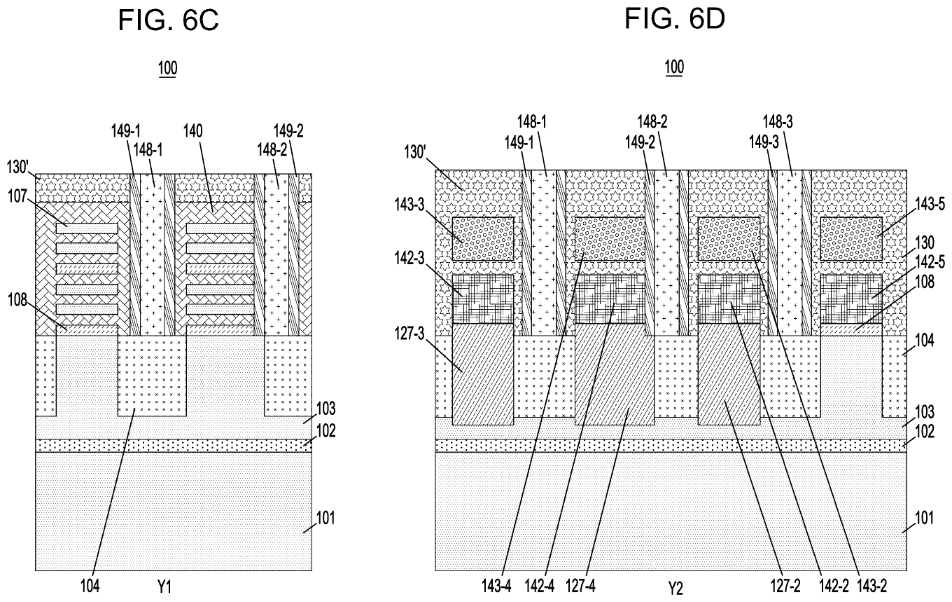

FIG. 6A depicts a top view of the semiconductor structure 100 with lines X, Y1 and Y2 on which the cross-sectional views of FIGS. 6B-6D are based, according to an embodiment of the invention. Referring to FIGS. 6A-6D, the OPLs 141 are removed, and a bi-layer of dielectric material is deposited in each of the openings 147. The bi-layers respectively comprise central dielectric layers 148-1, 148-2 and 148-3 (collectively “central dielectric layers 148”) and liner dielectric layers 149-1, 149-2 and 149-3 (collectively “liner dielectric layers 149”). The combination of the central dielectric layers 148 and liner dielectric layers 149 are referred to herein as gate cut portions. The central dielectric layers 148 comprise, for example, layers of an oxide, and the liner dielectric layers 149 comprise, for example, a nitride formed on side portions of the openings 147 around the central dielectric layers 148.

The dielectric materials of the central and liner dielectric layers 148 and 149 are deposited using deposition techniques such as, for example, CVD, PECVD, RFCVD, PVD, ALD, MBD, PLD, and/or LSMCD, followed by a planarization process, such as, CMP to remove excess portions of the dielectric material deposited on top of the additional ILD layer 130′. The dielectric material of the central dielectric layers 148 may comprise, but is not necessarily limited to, SiOₓ, and the dielectric material of the liner dielectric layers 149 may comprise, but is not necessarily limited to, SiN, SiON, SiCN, BN, SiBN, SiBCN and/or SiOCN.

Due to the configuration of the opening 147-2, a sidewall portion of the liner dielectric layer 149-2 contacts sidewall portions of the bottom and top source/drain regions 142-4 and 143-4 and fills in the step portion S of the sacrificial placeholder layer 127-4 to contact the sacrificial placeholder layer 127-4. In addition, a sidewall portion of the liner dielectric layer 149-2 contacts sidewall portions of the channel layers 107, MDI and BDI layers 109 and 108, and gate structures 140. As noted herein above, the bi-layers comprising the central dielectric layers 148 and liner dielectric layers 149 are gate cut portions.

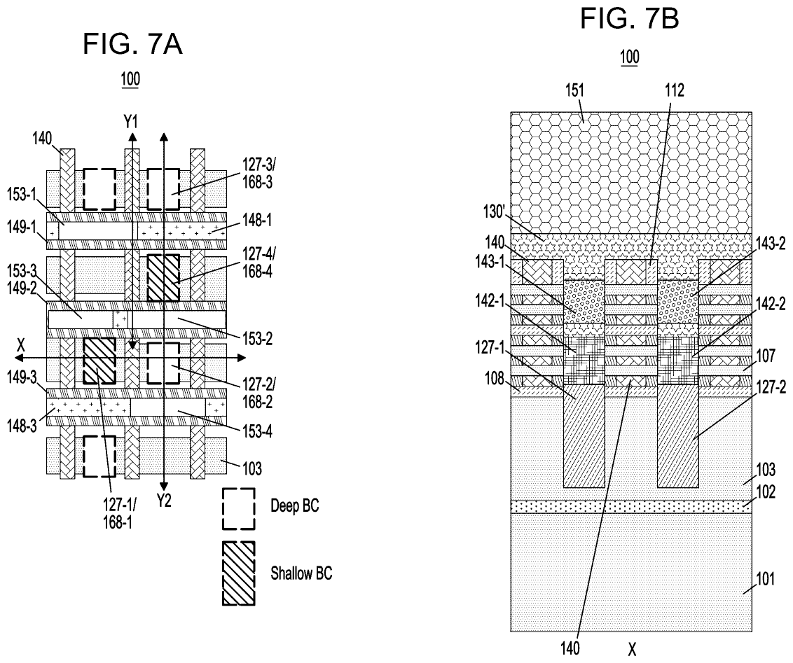

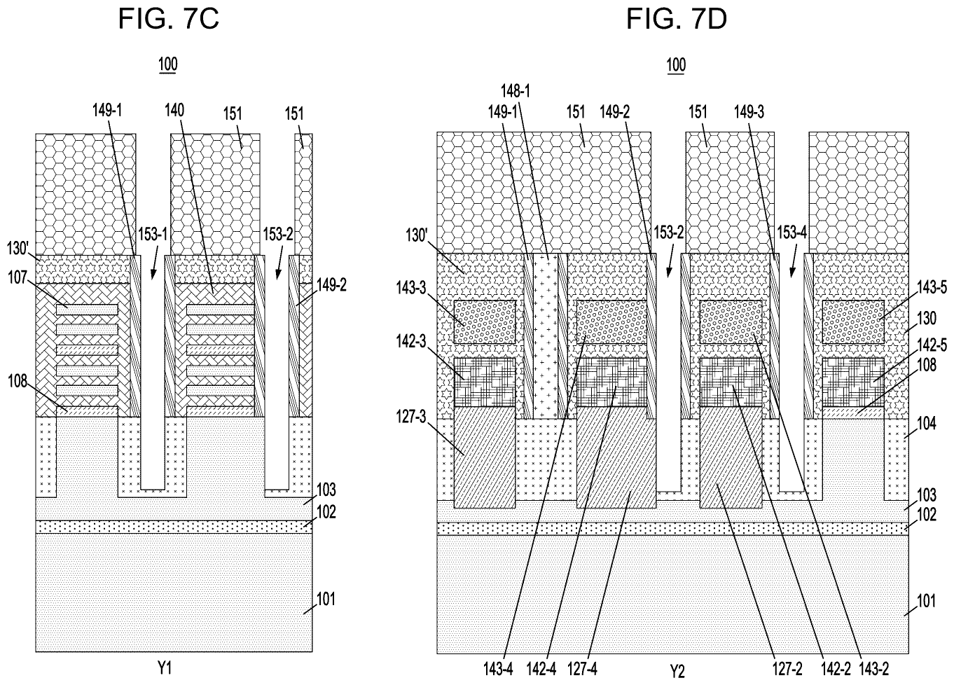

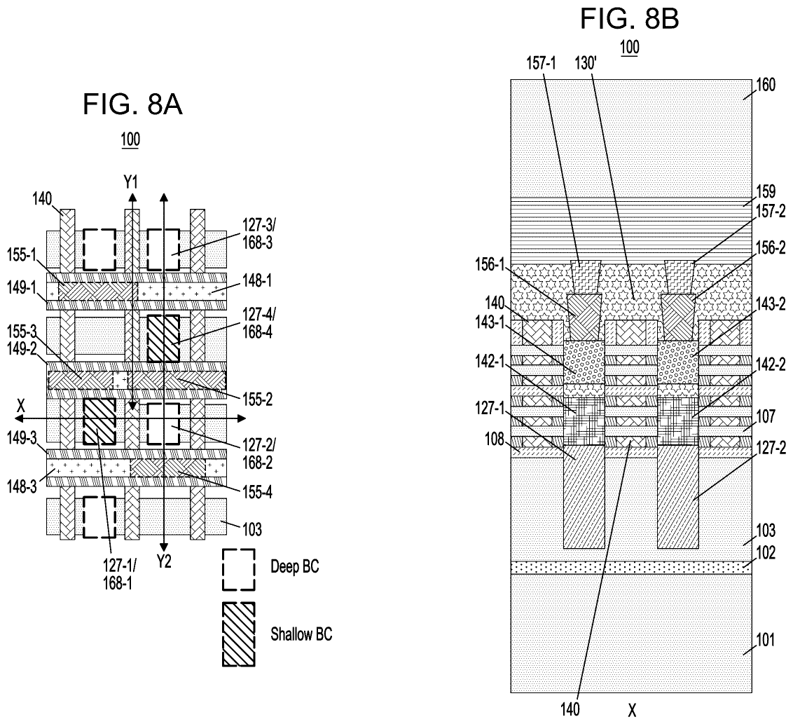

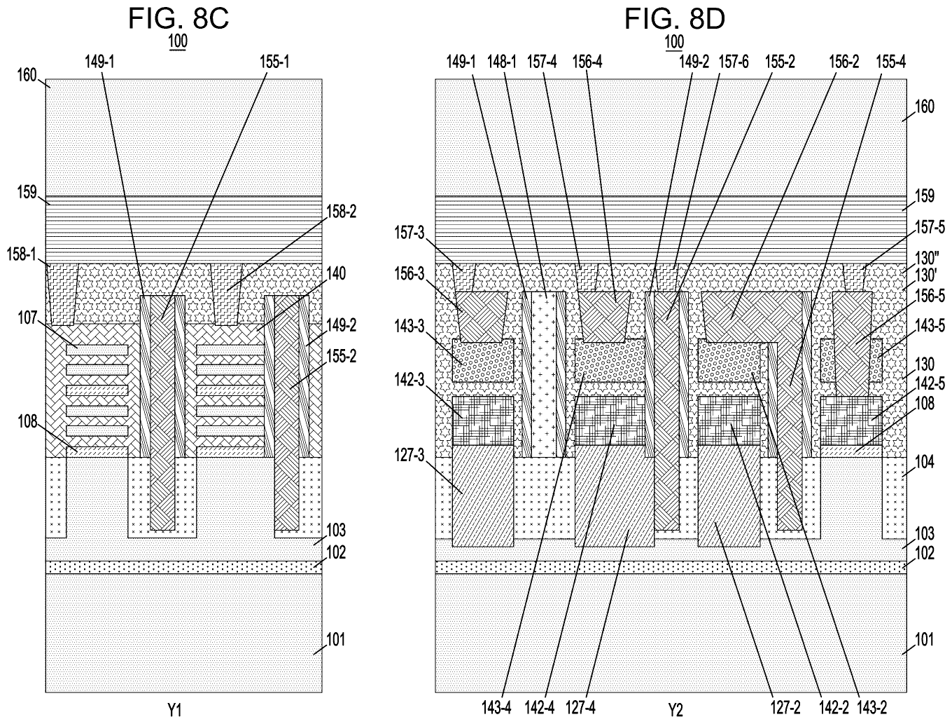

FIG. 7A depicts a top view of the semiconductor structure 100 with lines X, Y1 and Y2 on which the cross-sectional views of FIGS. 7B-7D are based, according to an embodiment of the invention. Referring to FIGS. 7A-7D, OPLs 151 are formed on the structure from FIGS. 6B-6D with openings exposing portions of central dielectric layers 148-1, 148-2 and 148-3. The exposed portions of central dielectric layers 148-1, 148-2 and 148-3 and underlying portions of corresponding isolation regions 104 are selectively removed with respect to the liner dielectric layers 149-1, 149-2 and 149-3 to create openings 153-1, 153-2, 153-3 and 153-4 (collectively “openings 153”). The selective removal is performed using, for example, by a plasma dry etch process. As can be seen in FIG. 7D, the removal of the portion of the underlying isolation region 104 to form opening 153-2 exposes a sidewall portion of the sacrificial placeholder layer 127-4. As explained in more detail herein, the openings 153 correspond to where deep vias 155-1, 155-2, 155-3 and 155-4 (collectively “deep vias 155”) will be formed (see FIGS. 8A-8D). Deep vias 155-3 and 155-4 corresponding to, for example, the sacrificial placeholders 127-3 or 127-2 having the same size as the active region, do not contact the sacrificial placeholders 127-3 or 127-2 or the corresponding backside source/drain contacts 168-3 or 168-2. The deep via 155-2 contacts the sacrificial placeholder 127-4 having a larger size than the active region, and the corresponding backside source/drain contact 168-4.

FIG. 8A depicts a top view of the semiconductor structure 100 with lines X, Y1 and Y2 on which the cross-sectional views of FIGS. 8B-15C are based, according to an embodiment of the invention. Referring to FIGS. 8B-8D, the OPLs 151 are removed, and the openings 153 are filled with conductive material to form the deep vias 155. For example, metal layers are deposited in the openings 153 to form the deep vias 155. The metal layers comprise, for example, a silicide layer, such as Ni, Ti, NiPt, etc., a metal adhesion layer, such as TiN, and a conductive metal fill layer, such as W, Al, Co, Ru, etc., and can be deposited using, for example, a deposition technique such as CVD, PECVD, RFCVD, PVD, ALD, MBD, PLD, LSMCD, sputtering and/or plating, followed by a planarization process such as, CMP to remove excess portions of the metal layers from on top of the additional ILD layer 130′.

Additional ILD material is deposited to form a second additional ILD layer 130″ on top of the additional ILD layer 130′. Then, frontside source/drain contacts 156-1, 156-2, 156-3, 156-4 and 156-5 (collectively “frontside source/drain contacts 156”) are formed in the ILD layers 130, 130′ and 130″. In forming the frontside source/drain contacts 156, openings are formed through portions of the ILD layers 130, 130′ and 130″. The openings expose portions of the top and bottom source/drain regions 143 or 142 on which the frontside source/drain contacts 156 are to be formed. According to an embodiment, masks are formed on parts of the second additional ILD layer 130″, and exposed portions of the ILD layers 130, 130′ and 130″ corresponding to where the openings are to be formed are removed using, for example, a dry etching process using a RIE or ion beam etch (IBE) process, a wet chemical etch process or a combination of these etching processes. A dry etch may be performed using a plasma. Such wet or dry etch processes include, for example, IBE by Ar/CHF3 based chemistry.

Metal layers comprising the same or similar materials as those used for the deep vias 155 are deposited in the openings to form the frontside source/drain contacts 156. The metal layers can be deposited using, for example, the same or similar deposition techniques as used for the deep vias 155, followed by a planarization process such as, CMP to remove excess portions of the metal layers from on top of the second additional ILD layer 130″.

The frontside source/drain contacts 156-1, 156-2, 156-3 and 156-4 contact respective ones of the top source/drain regions 143-1, 143-2, 143-3 and 143-4. The frontside source/drain contact 156-5 contacts the bottom source/drain region 142-5. The frontside source/drain contacts 156 extend through the ILD layers 130, 130′ and/or 130″ to land on and contact the corresponding top or bottom source/drain regions 143 or 142.

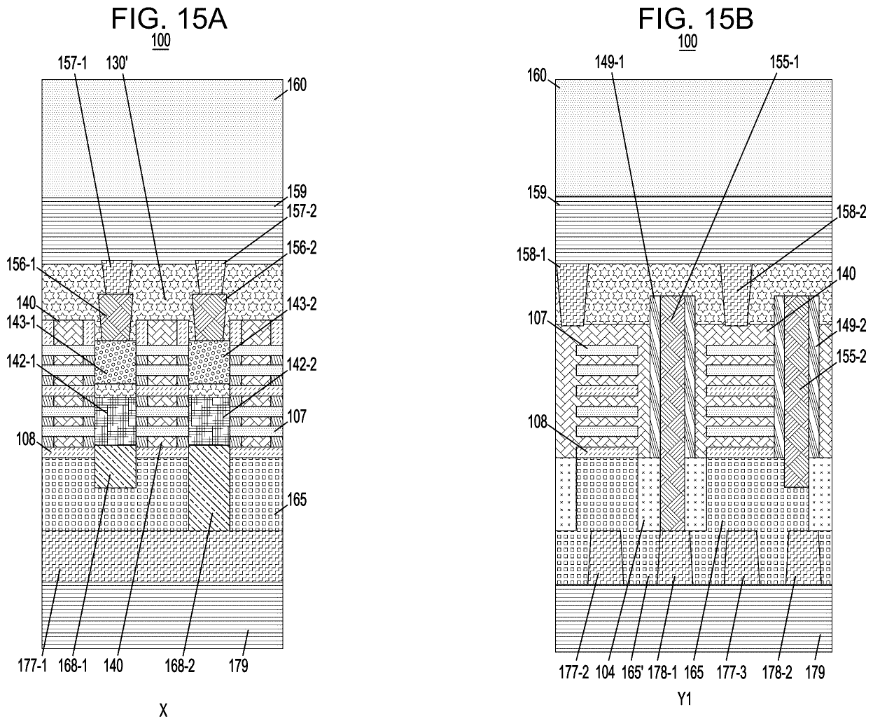

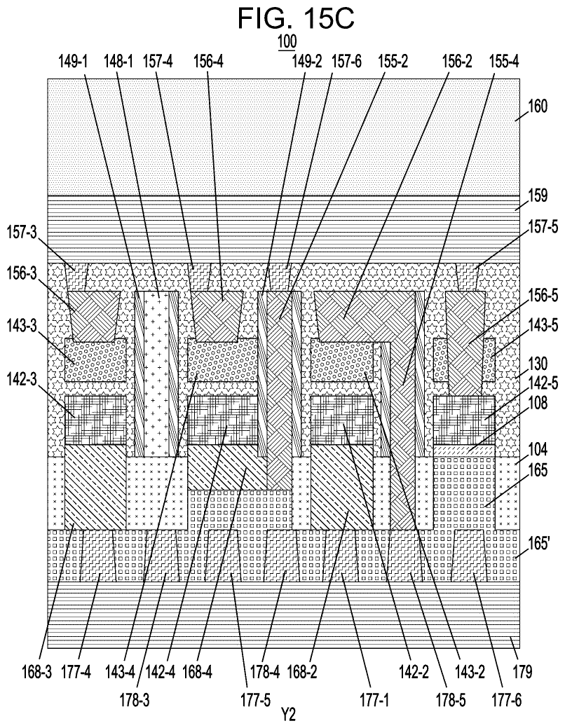

Frontside BEOL interconnects 159 are formed on the second additional ILD layer 130″. Frontside source/drain contact wires 157-1, 157-2, 157-3, 157-4, 157-5 and 157-6 (collectively “frontside source/drain contact wires 157”) extend through the second additional ILD layer 130″ from the frontside BEOL interconnects 159 to deliver source/drain signal voltages to source/drain regions. For example, frontside source/drain contact wires 157-1, 157-2, 157-3, 157-4 and 157-5 respectively connect the frontside BEOL interconnects 159 with frontside source/drain contacts 156-1, 156-2, 156-3, 156-4 and 156-5. As explained in more detail herein, a frontside source/drain contact wire 157-6 connects to deep via 155-2 to deliver source/drain voltages from the frontside BEOL interconnects 159 through the deep via 155-2 to a subsequently formed backside source/drain contact 168-4 (see, e.g., FIG. 15C).

A portion of the liner dielectric layer 149-3 is removed so that frontside source/drain contact 156-2, which has a larger horizontal dimension (e.g., width) than other frontside source/drain contacts 156, may extend and electrically connect to deep via 155-4. In turn, deep via 155-4 extends to a backside of the semiconductor structure 100. As explained in more detail in connection with FIG. 15C, the deep via 155-4 is connected a backside power delivery network (BSPDN) 179 to deliver power voltage to the top source/drain region 143-2. Referring to FIGS. 15A and 15C, as described in more detail herein, the connection of source/drain region 143-2 to frontside BEOL interconnect 159 is through frontside source/drain contact wire 157-2 and frontside source/drain contact 156-2. The connection of source/drain region 143-2 to BSPDN 179 is through frontside source/drain contact 156-2, deep via 155-4 and second backside power rail wire 178-5.

As can be seen in FIG. 8C, frontside gate contact wires 158-1 and 158-2 (collectively “frontside gate contact wires 158”) extend through the second additional ILD layer 130″ and the additional ILD layer 130′ from the frontside BEOL interconnects 159 to deliver gate signal voltages to respective gate structures 140 isolated from each other by the liner dielectric layers 149. The process and materials used for forming the frontside source/drain contact wires 157 and the frontside gate contact wires 158 are similar to those used for forming the frontside source/drain contacts 156 and/or deep vias 155.

A carrier wafer 160 is bonded to the frontside BEOL interconnects 159. The frontside BEOL interconnects 159 include various BEOL interconnect structures which may electrically connect to the frontside source/drain contacts 156 and the gate structures 140. The carrier wafer 160 may be formed of materials similar to that of the first and second semiconductor substrates 101 and 103, and may be formed over the frontside BEOL interconnects 159 using a wafer bonding process, such as dielectric-to-dielectric bonding.

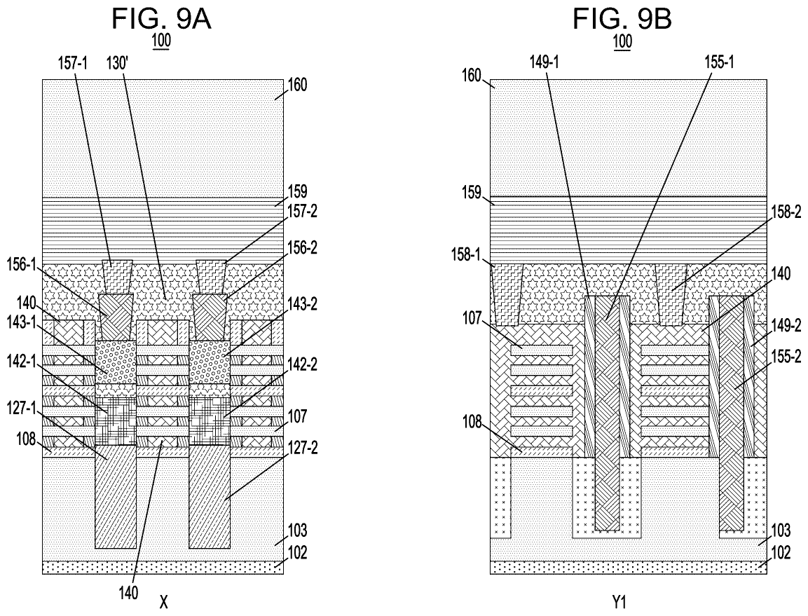

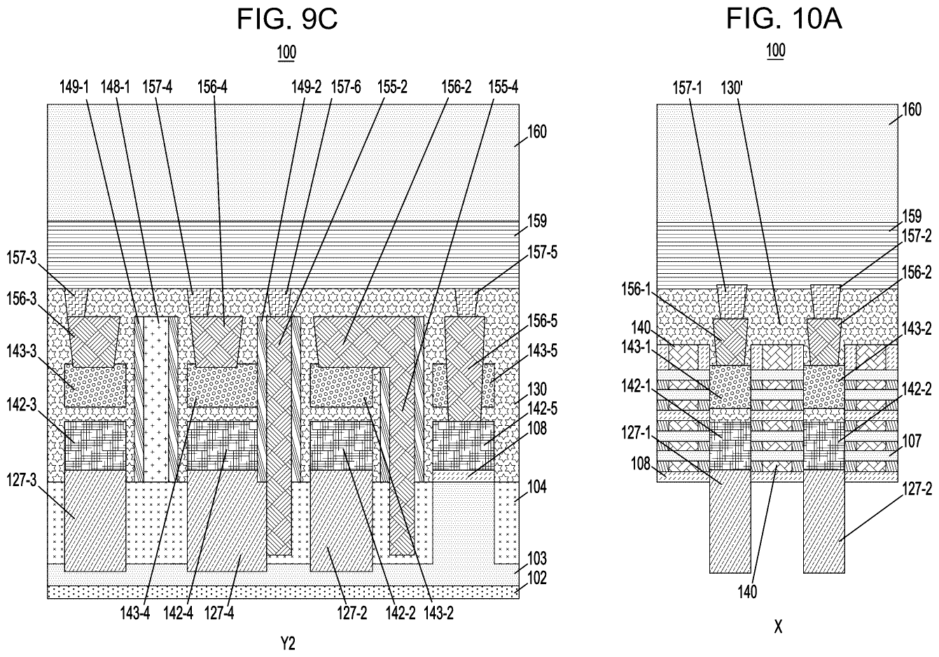

Referring to FIGS. 9A-9C, using the carrier wafer 160, the semiconductor structure 100 may be “flipped” (e.g., rotated 180 degrees) so that the structure is inverted. In addition, the first semiconductor substrate 101 is removed from the backside of the semiconductor structure 100. The removal process, which comprises etching of the first semiconductor substrate 101, stops at the etch stop layer 102. For example, the first semiconductor substrate 101 is selectively etched with an etchant that selectively etches silicon with respect to a material of the etch stop layer 102 (e.g., SiGe).

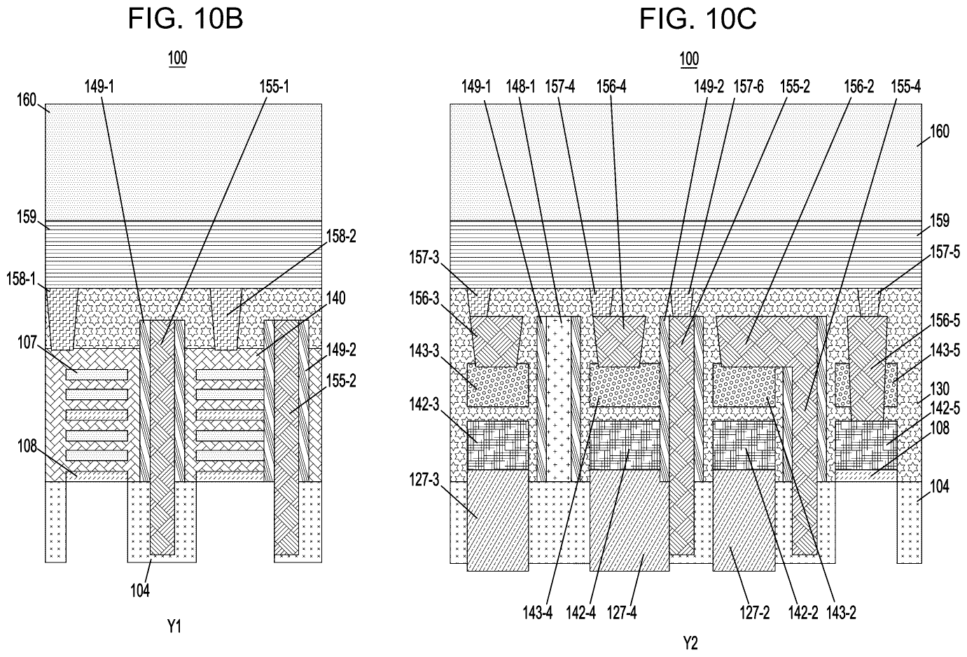

Referring to FIGS. 10A-10C, the etch stop layer 102 and the second semiconductor substrate 103 (e.g., silicon layer) are selectively removed from the semiconductor structure 100 with respect to the sacrificial placeholder layers 127 and the isolation regions 104. As shown in FIGS. 10A-10C, the etch stop layer 102 is removed, followed by removal of the second semiconductor substrate 103, wherein portions of the isolation regions 104, BDI layer 108, the sacrificial placeholder layers 127, dielectric liner layer 149-2 and deep via 155-2 are exposed. Etching processes for removal of the etch stop layer 102 include, for example, IBE by Ar/CHF3 based chemistry.

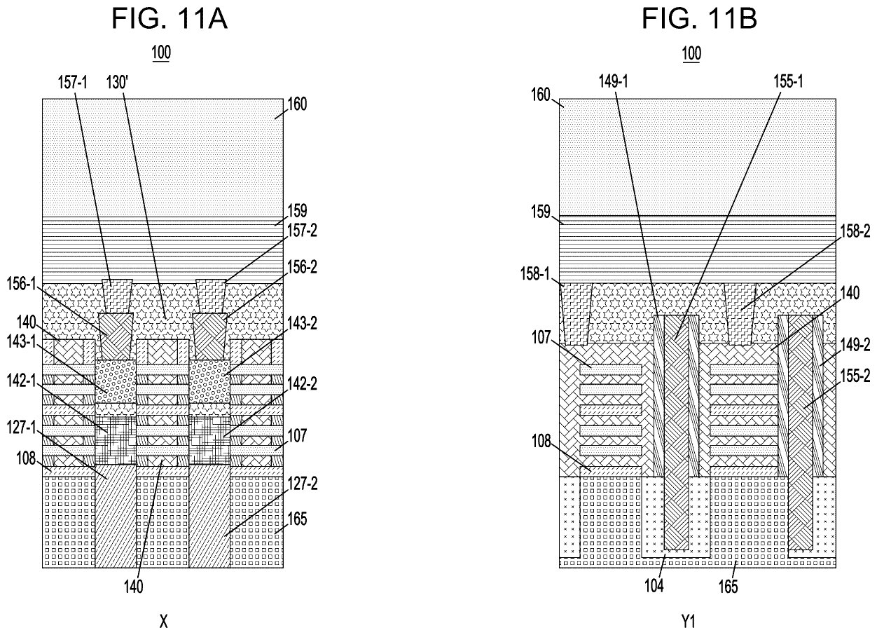

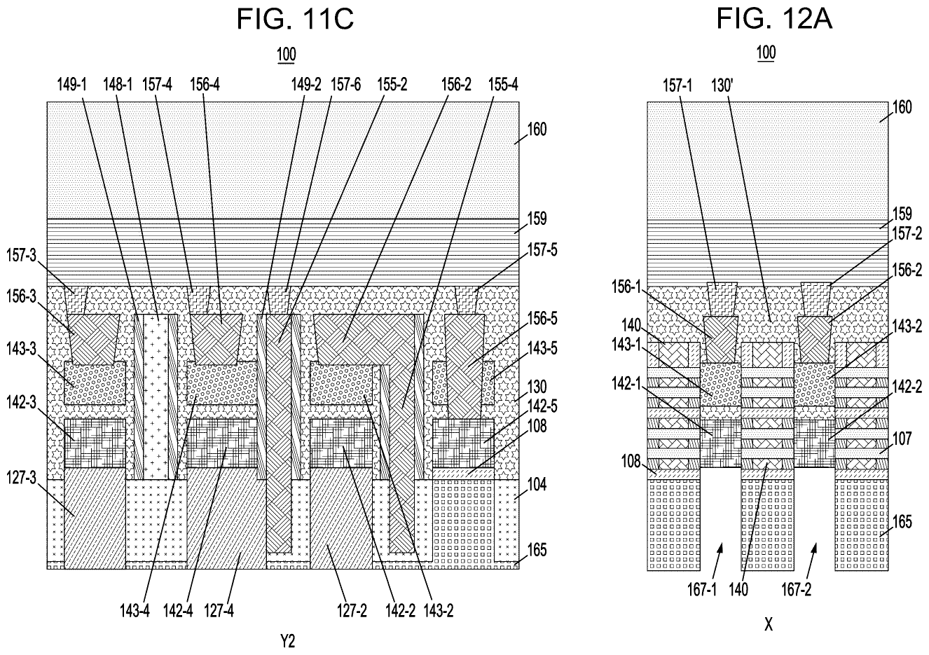

Referring to FIGS. 11A-11C, a backside ILD layer 165 is deposited to fill in areas formerly occupied by the second semiconductor substrate 103. The backside ILD layer 165 is deposited using deposition techniques such as, for example, CVD, PECVD, RFCVD, PVD, ALD, MBD, PLD, and/or LSMCD, followed by a planarization process, such as, CMP to remove excess portions of the backside ILD layer 165 deposited on top of the sacrificial placeholder layers 127 and isolation regions 104 so that the backside ILD layer 165 is coplanar with surfaces of the sacrificial placeholder layers 127. The surfaces of the sacrificial placeholder layers 127 are exposed following the CMP process. The backside ILD layer 165 may comprise, for example, SiOx, SiOC, SiOCN or some other dielectric.

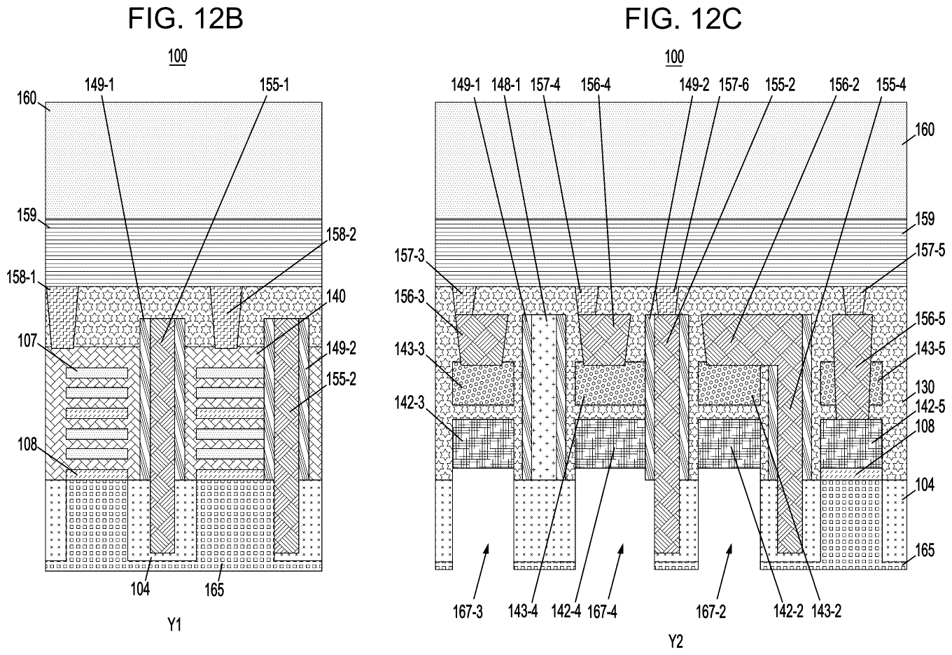

Referring to FIGS. 12A-12C, the sacrificial placeholder layers 127 are selectively removed to create openings 167-1, 167-2, 167-3 and 167-4 (collectively “openings 167”) exposing backside portions of the bottom source/drain regions 142-1, 142-2, 142-3 and 142-4. The opening 167-4 further exposes a sidewall of the deep via 155-2. The sacrificial placeholder layers 127 are removed using, for example, a selective dry or wet etch process.

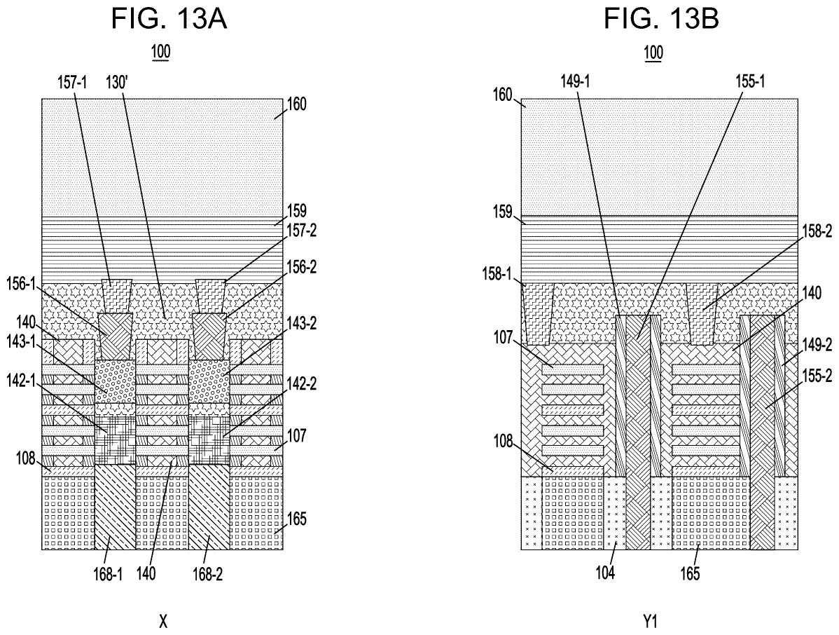

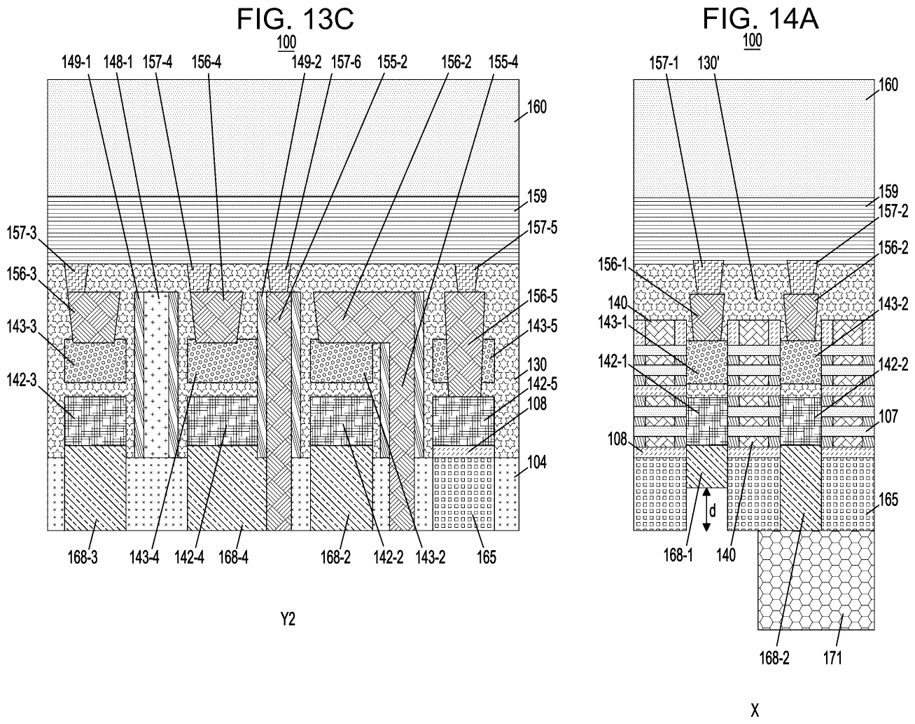

Referring to FIGS. 13A-13C, backside source/drain contacts 168-1, 168-2, 168-3 and 168-4 (collectively “backside source/drain contacts 168”) are formed in the backside ILD layer 165 in the openings 167 left by the removal of the sacrificial placeholder layers 127. Metal layers are deposited in the openings to form the backside source/drain contacts 168. The metal layers comprise, for example, a silicide layer, such as Ni, Ti, NiPt, etc., a metal adhesion layer, such as TiN, and a conductive metal fill layer, such as W, Al, Co, Ru, etc., and can be deposited using, for example, a deposition technique such as CVD, PECVD, RFCVD, PVD, ALD, MBD, PLD, LSMCD, sputtering and/or plating, followed by a planarization process such as, CMP to remove excess portions of the metal layers from on top of the backside ILD layer 165.

The backside source/drain contacts 168 contact respective backsides of the bottom source/drain regions 142. The backside source/drain contacts 168 extend through the backside ILD layer 165 to land on and contact the backsides of the corresponding bottom source/drain regions 142. In addition, as shown in FIG. 13C, at least a horizontal dimension (e.g., width) of the backside source/drain contact 168-4 is larger than the horizontal dimension (e.g., width) of the bottom source/drain region 142-4 such that a sidewall of the backside source/drain contact 168-4 is out of alignment (e.g., not coplanar) with a sidewall of the bottom source/drain region 142-4. The sidewall of the backside source/drain contact 168-4 that is out of alignment with the sidewall of the bottom source/drain region 142-4 contacts a sidewall of the deep via 155-2, which as noted herein above, is connected to the frontside BEOL interconnects 159 through the frontside source/drain contact wire 157-6. In illustrative embodiments, the remaining backside source/drain contacts 168-1, 168-2 and 168-3 are the same size (e.g., have the same horizontal dimension (e.g., width)) as the bottom source/drain regions 142-1, 142-2 and 142-3 such that the sidewalls of the backside source/drain contacts 168-1, 168-2 and 168-3 are aligned (e.g., coplanar) with the sidewalls of the bottom source/drain regions 142-1, 142-2 and 142-3.

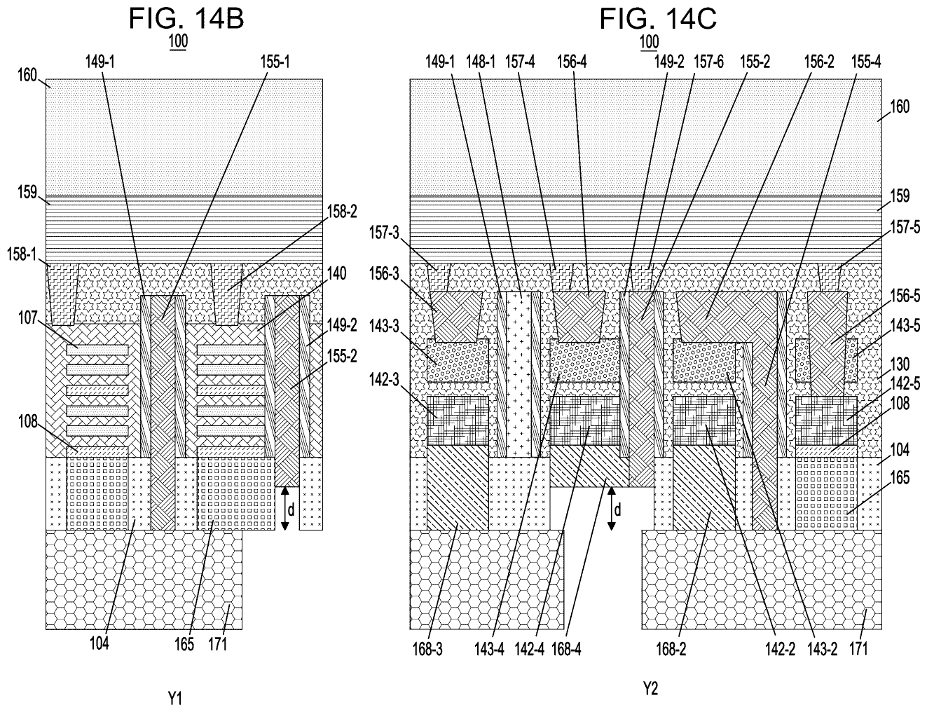

Referring to FIGS. 14A-14C, some of the backside source/drain contacts (e.g., backside source/drain contacts 168-1 and 168-4) are recessed with respect to the outer surface of the backside ILD layer 165 to create “shallow” backside source/drain contacts, with the remaining backside source/drain contacts (e.g., backside source/drain contacts 168-2 and 168-3) being “deep” backside source/drain contacts. In addition, deep via 155-2 is also recessed with respect to the outer surface of the backside ILD layer 165. The recessing is performed by depositing OPLs 171 on the backside ILD layer 165, wherein portions where the OPLs 171 are not formed expose the backside source/drain contacts 168-1 and 168-4 and deep via 155-2 that are to be recessed. The recessing is performed using, for example, a selective wet or dry etch process. As can be seen, outer surfaces of the backside source/drain contacts 168-1 and 168-4 and deep via 155-2 are recessed at a particular depth d.

Referring to FIGS. 15A-15C, the OPLs 171 are removed and additional backside ILD material is deposited to form an additional backside ILD layer 165′ on the backside ILD layer 165. Then, first backside power rail wires 177-1, 177-2, 177-3, 177-4, 177-5 and 177-6 (collectively “first backside power rail wires 177”) and second backside power rail wires 178-1, 178-2, 178-3, 178-4 and 178-5 (collectively “second backside power rail wires 178”) are formed in the additional backside ILD layer 165′. The first and second backside power rail wires 177 and 178 respectively correspond to negative power supply lines (e.g., ground or source voltage (VSS) lines) and positive power supply lines (e.g., drain voltage (VDD) lines). The first and second backside power rail wires 177 and 178 are also referred to herein as backside power rails. In forming the first and second backside power rail wires 177 and 178, openings are formed through portions of the additional backside ILD layer 165′. Some of the openings (e.g., openings corresponding to first backside power rail wires 177-1 and 177-4) expose portions of the backside source/drain contacts 168-2 and 168-3 (e.g., deep backside contacts) on which the first backside power rail wires 177-1 and 177-4 are to be formed. The openings corresponding to second backside power rail wires 178-1 and 178-5 expose the deep vias 155-1 and 155-4 on which the second backside power rail wires 178-1 and 178-5 are to be formed. As can be seen, the backside recessed source/drain contacts 168-1 and 168-4 (e.g., shallow backside contacts) and recessed deep via 155-2 are isolated from the first and second backside power rail wires 177 and 178 by the backside ILD layer 165.

The first and second backside power rail wires 177 and 178, also referred to herein as power elements or backside power rails, are formed in the additional backside ILD layer 165′ by forming trenches in the additional backside ILD layer 165′ and filling the trenches with conductive material. Trenches are respectively opened in the additional backside ILD layer 165′ using, for example, lithography followed by RIE. The first and second backside power rail wires 177 and 178 are formed in the trenches by filling the trenches with conductive material, such as, for example, electrically conductive material including, but not necessarily limited to, tungsten, cobalt, zirconium, tantalum, titanium, aluminum, ruthenium, and/or copper. A liner layer (not shown) including, for example, titanium and/or titanium nitride, may be formed on side and bottom surfaces of the trenches before filling the trenches with the conductive material. Deposition of the conductive material can be performed using one or more deposition techniques, including, but not necessarily limited to, CVD, PECVD, PVD, ALD, MBD, PLD, LSMCD, and/or spin-on coating, followed by planarization using a planarization process, such as, for example, CMP.

The backside ILD layer 165 and the additional backside ILD layer 165′ fill in the vacant areas on lateral sides of the backside source/drain contacts 168, lateral sides of the deep vias and on lateral sides of the first and second backside power rail wires 177 and 178. The backside source/drain contacts 168 are adjacent and contact isolation regions 104.

Backside power delivery network (BSPDN) 179 (also referred to herein as backside interconnects) are formed on the additional backside ILD layer 165′ and on the first and second backside power rail wires 177 and 178. The BSPDN 179 includes various BSPDN structures such as, but not necessarily limited to, interconnects in a power supply path from voltage regulator modules (VRMs) to circuits. The interconnects can comprise, for example, power and ground planes in circuit boards, cables, connectors and capacitors associated with a power supply. Backside power delivery prevents BEOL routing congestion, resulting in power performance benefits.

In this case, the transistor corresponding to the first type of backside contact is a gate-all-around (GAA) transistor. A second type of backside contact has an enlarged size (e.g., larger horizontal dimension in the cross-sectional views) compared to a corresponding source/drain region on which the second type of backside contact is formed. In this case, the transistor corresponding to the second type of backside source/drain contact is a forksheet transistor.

As described herein above, the first type of backside source/drain contact is a deep backside contact that is connected to backside power (e.g., to a BSPDN). The second type of backside contact is a shallow backside contact that is connected to frontside signal wires through a deep via. In illustrative embodiments, a liner dielectric layer isolates the deep via from forksheet channels. Additionally, the second type of backside source/drain contact (e.g., extended backside contact) connects to a deep via sidewall.

Backside source/drain contacts 168-2 and 168-3 are the same size (e.g., same horizontal dimension in the cross-sectional views) as the bottom source/drain regions 142-2 and 142-3 on which the backside source/drain contacts 168-2 and 168-3 are formed. The backside source/drain contacts 168-2 and 168-3 are deep backside contacts connected to the BSPDN 179. In illustrative embodiments, the bottom source/drain regions 142-2 and 142-3 correspond to gate-all-around (GAA) transistors. Backside source/drain contact 168-4, which has an enlarged size (e.g., larger horizontal dimension in the cross-sectional views) compared to bottom source/drain region 142-4 on which backside source/drain contact 168-4 is formed, is a shallow backside contact connected to frontside BEOL interconnects 159 through a deep via 155-2. In illustrative embodiments, the bottom source/drain region 142-4 corresponds to a forksheet transistor. As can be seen in FIG. 15B, liner dielectric layer 149-2 isolates the deep via 155-2 from channel layers 107 and gate structures 140 of the forksheet transistor. Additionally, the backside source/drain contact 168-4 (e.g., extended backside contact) connects to a sidewall of the deep via 155-2. In a forksheet FET, an nFET and a pFET are integrated in the same structure, where a dielectric layer (e.g., central and liner dielectric layers 148-2 and 149-2) separate the nFET and pFET. In illustrative embodiments, in connection with the forksheet transistor, the plurality of channel layers 107 contact the dielectric layer of the gate cut portion (e.g., liner dielectric layer 149-2) at an edge where the sidewall of the backside source/drain contact 168-4 is out of alignment with the sidewall of the bottom source/drain region 142-4.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETs, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

As noted above, the embodiments provide structures for and techniques for forming an extended backside contact for a stacked FET. In the illustrative embodiments, for stacked FETs, a first type of backside contact is the same size (e.g., same horizontal dimension in the cross-sectional views) as a corresponding source/drain region on which the first type of backside contact is formed. In this case, the transistor corresponding to the first type of backside contact is a gate-all-around (GAA) transistor. A second type of backside contact has an enlarged size (e.g., larger horizontal dimension in the cross-sectional views) compared to a corresponding source/drain region on which the second type of backside contact is formed. In this case, the transistor corresponding to the second type of backside contact is a forksheet transistor.

As described herein above, the first type of backside contact is a deep backside contact that is connected to backside power (e.g., to a BSPDN). The second type of backside contact is a shallow backside contact that is connected to frontside signal wires through a deep via. In illustrative embodiments, a liner dielectric layer isolates the deep via from forksheet channels. Additionally, the second type of backside contact (e.g., extended backside contact) connects to a deep via sidewall.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a first transistor comprising a first source/drain region disposed on a side of the first transistor;
a second transistor comprising a second source/drain region disposed on a side of the second transistor;
a first source/drain contact disposed under the first source/drain region, wherein sidewalls of the first source/drain contact are aligned with sidewalls of the first source/drain region; and
a second source/drain contact disposed under the second source/drain region, wherein a dimension of the second source/drain contact is larger than a dimension of the second source/drain region such that at least one sidewall of the second source/drain contact is out of alignment with at least one sidewall of the second source/drain region;
wherein the second transistor comprises a plurality of channel layers contacting a dielectric layer of a gate cut portion.

2. The semiconductor device of claim 1, further comprising:
a third transistor stacked on the first transistor and comprising a third source/drain region disposed on a side of the third transistor, wherein the third source/drain region is stacked on the first source/drain region; and
a fourth transistor stacked on the second transistor and comprising a fourth source/drain region disposed on a side of the fourth transistor, wherein the fourth source/drain region is stacked on the second source/drain region.

3. The semiconductor device of claim 2, further comprising a via disposed along a side of the fourth source/drain region and the second source/drain region, wherein the at least one sidewall of the second source/drain contact contacts a sidewall of the via.

4. The semiconductor device of claim 3, wherein the dielectric layer of the gate cut portion is disposed between the fourth source/drain region and the via, and between the second source/drain region and the via.

5. The semiconductor device of claim 3, wherein the fourth transistor comprises a plurality of channel layers contacting the dielectric layer of the gate cut portion.

6. The semiconductor device of claim 5, the dielectric layer of the gate cut portion is disposed between the via and the plurality of channel layers of the second transistor and between the via and the plurality of channel layers of the fourth transistor.

7. The semiconductor device of claim 3, wherein:
the via is connected to a voltage source disposed on a first side of the semiconductor device; and
the first and the second source/drain contacts are disposed on a second side of the semiconductor device opposite the first side.

8. The semiconductor device of claim 7, wherein the first source/drain contact is connected to a voltage source disposed on the second side of the semiconductor device.

9. The semiconductor device of claim 1, wherein the first and the second source/drain contacts are disposed in a dielectric layer, and the first source/drain contact is disposed at a greater depth in the dielectric layer than the second source/drain contact.

10. The semiconductor device of claim 1, wherein the first transistor comprises a gate-all-around transistor, and the second transistor comprises a forksheet transistor.

11. A semiconductor device comprising:
a first transistor comprising a first source/drain region disposed on a side of the first transistor;
a second transistor stacked on the first transistor and comprising a second source/drain region disposed on a side of the second transistor, wherein the second source/drain region is stacked on the first source/drain region; and
a source/drain contact disposed under the first source/drain region, wherein a dimension of the source/drain contact is larger than a dimension of the first source/drain region such that at least one sidewall of the source/drain contact is out of alignment with at least one sidewall of the first source/drain region;
wherein the first transistor comprises a plurality of channel layers contacting a dielectric layer of a gate cut portion.

12. The semiconductor device of claim 11, further comprising a via disposed along a side of the second source/drain region and the first source/drain region, wherein the at least one sidewall of the source/drain contact contacts a sidewall of the via.

13. The semiconductor device of claim 12, wherein the dielectric layer of the gate cut portion is disposed between the second source/drain region and the via, and between the first source/drain region and the via.

14. The semiconductor device of claim 12, wherein the second transistor comprises a plurality of channel layers contacting the dielectric layer of the gate cut portion, wherein the dielectric layer of the gate cut portion is disposed between the via and the plurality of channel layers of the second transistor.

15. The semiconductor device of claim 12, wherein:
the via is connected to a voltage source disposed on a first side of the semiconductor device; and
the source/drain contact is disposed on a second side of the semiconductor device opposite the first side.

16. The semiconductor device of claim 11, wherein the plurality of channel layers contact the dielectric layer of the gate cut portion where the at least one sidewall of the source/drain contact is out of alignment with the at least one sidewall of the first source/drain region.

17. A semiconductor device comprising:
a stacked structure comprising a plurality of gate structures alternately stacked with a plurality of channel layers;
at least one source/drain region disposed on a side of the stacked structure; and
a source/drain contact disposed under the at least one source/drain region, wherein a dimension of the source/drain contact is larger than a dimension of the at least one source/drain region such that at least one sidewall of the source/drain contact is out of alignment with at least one sidewall of the at least one source/drain region;
wherein the plurality of channel layers contact a dielectric layer of a gate cut portion.

18. The semiconductor device of claim 17, further comprising a via disposed along a side of the at least one source/drain region, wherein the at least one sidewall of the source/drain contact contacts a sidewall of the via.

19. The semiconductor device of claim 18, wherein the dielectric layer of the gate cut portion is disposed between the at least one source/drain region and the via.

20. The semiconductor device of claim 18, wherein the dielectric layer of the gate cut portion is disposed between the via and the plurality of gate structures and the plurality of channel layers.
